(19) United States
(12) Patent Application Publication
(10) Pub. No.: US 2026/0052695 A1
(43) Pub. Date: Feb. 19, 2026

(54) SEMICONDUCTOR DEVICES AND DATA STORAGE SYSTEMS INCLUDING THE SAME

(71) Applicant: SAMSUNG ELECTRONICS CO., LTD., Suwon-si (KR)

(72) Inventors: Hakseon Kim, Suwon-si (KR); Seahoon Lee, Suwon-si (KR); Sejun Park, Suwon-si (KR); Seongpil Chang, Suwon-si (KR)

(21) Appl. No.: 19/054,577

(22) Filed: Feb. 14, 2025

(30) Foreign Application Priority Data
Aug. 16, 2024 (KR) 10-2024-0109504

(51) Int. Cl. H10B 43/40; H10B 41/27; H10B 41/41; H10B 43/27

(52) U.S. Cl. CPC H10B 43/40; H10B 41/27; H10B 41/41; H10B 43/27

(57) ABSTRACT

Semiconductor devices, systems, and manufacturing methods are provided. In one aspect, a semiconductor device includes: a substrate including an upper surface and a lower surface; a gate structure having a first length in a first direction and disposed on the substrate; a drain region extending from the upper surface of the substrate on a first side of the gate structure; a source region extending from the upper surface of the substrate and on a second side of the gate structure; a channel region extending from the upper surface of the substrate, below the gate structure, and between the drain region and the source region; and a first separation trench structure extending from the lower surface of the substrate in a second direction, in a boundary region between the channel region and the drain region, and spaced apart from the upper surface of the substrate.

### CROSS-REFERENCE TO RELATED APPLICATIONS

This application claims priority under 35 U.S.C. § 119 to Korean Patent Application No. 10-2024-0109504 filed on Aug. 16, 2024, in the Korean Intellectual Property Office, the disclosure of which is incorporated herein by reference in its entirety.

### BACKGROUND

In a data storage system, a semiconductor device capable of storing a large amount of data is desired. Accordingly, a method of increasing the data storage capacity of a semiconductor device has been researched. For example, as one of the methods of increasing the data storage capacity of a semiconductor device, a semiconductor device including memory cells arranged three-dimensionally instead of memory cells arranged two-dimensionally has been proposed. Additionally, circuit elements driving the memory cells include complementary metal-oxide-semiconductor (CMOS) transistors, and high-voltage transistors to which a voltage of several to several tens of volts is applied.

### SUMMARY

An aspect of the present disclosure is to provide a semiconductor device in which off characteristics are improved by preventing Drain induced Barrier Lowering (DiBL) by forming a separation structure that blocks a drain region and a lower portion of the channel region in a high-voltage transistor.

An aspect of the present disclosure is to provide a data storage system including a semiconductor device having improved off characteristics by blocking current flow from a drain region to a region other than a channel region in a high-voltage transistor.

A semiconductor device according to one or more implementations includes: a substrate including an upper surface and a lower surface; a gate structure on the upper surface of the substrate and having a first length in a first direction parallel to the upper surface; a drain region disposed in the substrate and extending from the upper surface of the substrate on a first side of the gate structure in the first direction; a source region disposed in the substrate and extending from the upper surface of the substrate on a second side of the gate structure opposite to the first side in the first direction; a channel region disposed in the substrate and extending from the upper surface of the substrate below the gate structure between the drain region and the source region; and a first separation trench structure extending from the lower surface of the substrate, in a second direction, perpendicular to the first direction, disposed in a boundary region between the channel region and the drain region, and spaced apart from the upper surface of the substrate.

A semiconductor device according to one or more implementations includes: a cell structure including gate electrodes, channel structures extending through the gate electrodes, and contact plugs connected to the gate electrodes; and a peripheral circuit structure including a substrate electrically connected to the cell structure, the substrate having an upper surface and a lower surface, and a first element region and a second element region in the substrate, N-type first circuit elements and P-type second circuit elements in the first element region, and N-type third circuit elements and P-type fourth circuit elements in the second element region, and at least one of the N-type third circuit elements includes: a gate structure on the upper surface of the substrate, the gate structure including a gate dielectric layer having a thickness greater than a thickness of gate dielectric layers of the N-type first and P-type second circuit elements, and a gate conductive layer on the gate dielectric layer; a drain region disposed in the substrate and extending from the upper surface of the substrate on a first side of the gate structure in a first direction, parallel to the upper surface of the substrate; a source region disposed in the substrate and extending from the upper surface of the substrate on a second side of the gate structure in the first direction; a channel region disposed in the substrate and extending from the upper surface of the substrate below the gate structure, between the drain region and the source region; and a separation trench structure extending from the lower surface of the substrate, in a second direction, perpendicular to the first direction, and spaced apart from the upper surface of the substrate, the separation trench structure disposed in a boundary region between the channel region and the drain region.

A data storage system includes: a semiconductor storage device including a substrate, a first substrate structure including first to fourth circuit elements on the substrate, a second substrate structure including memory cells, and an input/output pad electrically connected to the first to fourth circuit elements; and a controller electrically connected to the semiconductor storage device through the input and output pad and controlling the semiconductor storage device, and the first circuit elements include NMOS transistors for low-voltage driving, the second circuit elements include PMOS transistors for low-voltage driving, the third circuit elements include NMOS transistors for high-voltage driving, and the fourth circuit elements include PMOS transistors for high-voltage driving, and each of the third circuit elements includes: a gate structure on an upper surface of the substrate, the gate structure including a gate dielectric layer having a thickness greater than a thickness of gate dielectric layers of the first and second circuit elements, and a gate conductive layer on the gate dielectric layer; a drain region disposed in the substrate and extending from the upper surface of the substrate on a first side of the gate structure in a first direction, parallel to the upper surface of the substrate; a source region disposed in the substrate from the upper surface of the substrate on a second side of the gate structure in the first direction; a channel region disposed in the substrate and extending from the upper surface of the substrate below the gate structure between the drain region and the source region; and a separation trench structure extending from a lower surface of the substrate in a second direction, perpendicular to the first direction, the separation trench structure disposed in a boundary region between the channel region and the drain region, and the separation trench structure having an upper end spaced apart from the upper surface of the substrate.

In order to prevent the diffusion of a depletion region of a drain region to which a high voltage is applied in an NMOS transistor among high-voltage transistors, off characteristic may be improved by forming a separation structure that physically blocks the drain region and a substrate of a lower portion of a channel region, between the drain region and the channel region. Accordingly, reliability of the device may be improved.

The aspects to be solved by the present disclosure are not limited to the above-mentioned aspects, and will be clearly understood by those skilled in the art from the following description.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a schematic plan view of an example semiconductor device;

FIG. 2 is a partially enlarged view of the semiconductor device according to one or more implementations of FIG. 1.

FIGS. 3A to 3D are cross-sectional views of a semiconductor device according to one or more implementations of FIG. 1;

FIGS. 4 and 5 are schematic cross-sectional views of an example semiconductor device;

FIG. 6A is a plan view of an example semiconductor device, and FIG. 6B is a cross-sectional view of the example semiconductor device of FIG. 6A;

FIG. 7 is a schematic cross-sectional view of an example semiconductor device;

FIG. 8 is a schematic cross-sectional view of an example semiconductor device that is a memory device;

FIGS. 9A and 9B are partially enlarged views of the semiconductor device of FIG. 8;

FIG. 10 is a cross-sectional view of an example semiconductor device;

FIGS. 11A to 11K are schematic cross-sectional views illustrating an example method of manufacturing a semiconductor device;

FIG. 12 is a view schematically illustrating an example data storage system including a semiconductor device; and

FIG. 13 is a perspective view schematically illustrating an example data storage system including a semiconductor device.

### DETAILED DESCRIPTION

Hereinafter, example implementations of the present disclosure will be described with reference to the accompanying drawings. Hereinafter, it may be understood that the expressions such as “on,” “above,” “upper,” “below”, “beneath,” “lower,” and “side surface,” merely indicated based on drawings, except that they are indicated by drawings and referred to separately.

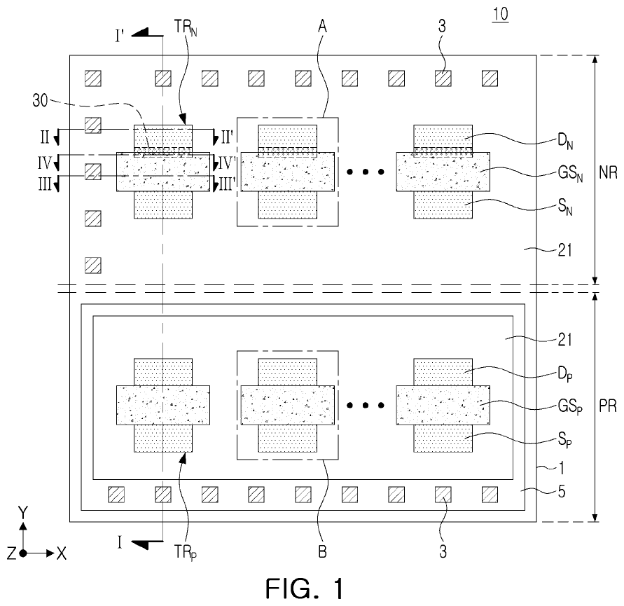

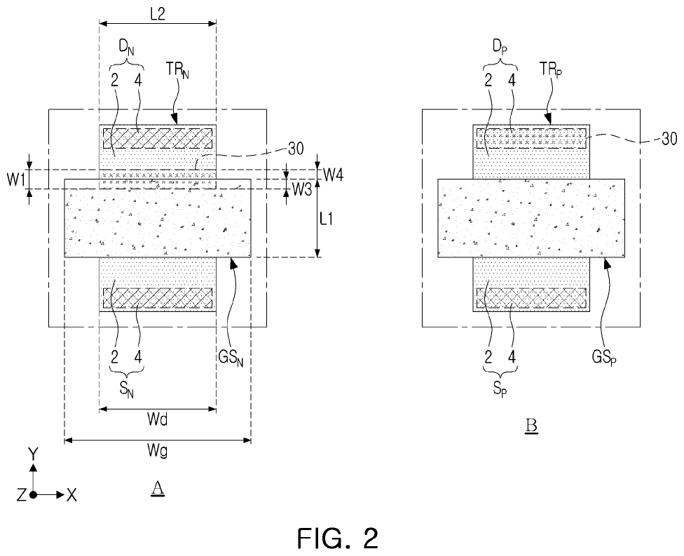

FIG. 1 is a schematic plan view of a semiconductor device according to one or more implementations. FIG. 2 is a partially enlarged view of the semiconductor device according to one or more implementations of FIG. 1.

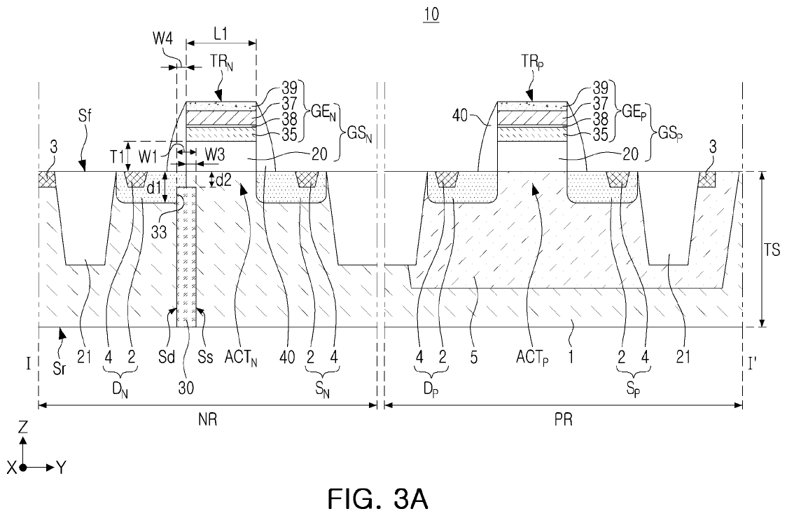

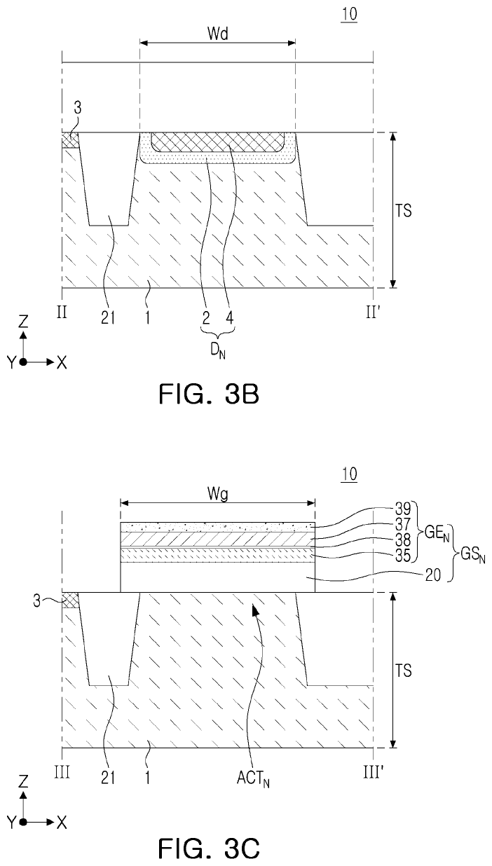

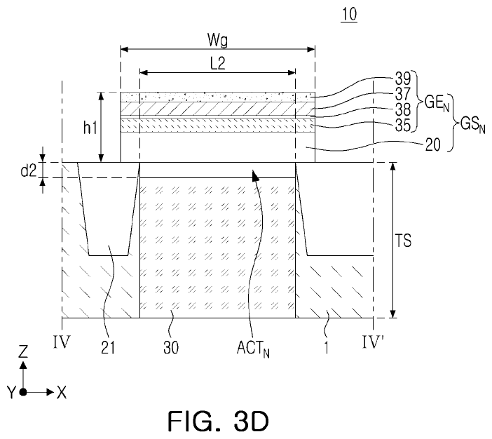

FIGS. 3A to 3D are cross-sectional views of a semiconductor device according to one or more implementations of FIG. 1, and FIG. 3A is a cross-sectional view taken along line I-I′ of the semiconductor device of FIG. 1, FIG. 3B is a cross-sectional view taken along line II-II′ of the semiconductor device of FIG. 1, FIG. 3C is a cross-sectional view taken along line III-III′ of the semiconductor device of FIG. 1, and FIG. 3D is a cross-sectional view taken along line IV-IV′ of the semiconductor device of FIG. 1.

A semiconductor device 10 may include an NMOS region NR and a PMOS region PR. The semiconductor device 10 may include a substrate 1, element isolating layers 21 in the substrate 1, first circuit elements TR_{N} as NMOS transistors disposed on the substrate 1 in the NMOS region NR, and second circuit elements TR_{P} as PMOS transistors disposed on the substrate 1 in the PMOS region PR.

The substrate 1 may have an upper surface Sf extending in an X-direction and a Y-direction and a lower surface Sr opposing the upper surface Sf. The element isolating layers 21 may be formed on the substrate 1 to define active regions. First and second source/drain regions D_{N}, S_{N}, D_{P} and S_{P} including impurities may be disposed in some of the active regions. The substrate 1 may include a semiconductor material, for example, a group IV semiconductor, a group III-V compound semiconductor, or a group II-VI compound semiconductor. For example, the substrate 1 may be provided as a single-crystal silicon bulk wafer.

In a case in which both the NMOS region NR and the PMOS region PR are disposed in the substrate 1, when the substrate 1 is a P-type substrate, a well region 5 may be disposed in the substrate 1 to define the PMOS region PR. The well region 5 may be a region doped with N-type impurities. However, the present disclosure is not limited thereto, and a well region doped with P-type impurities may be further disposed in the substrate 1 to define the NMOS region NR. Substrate pad regions 3 for applying a body voltage to the NMOS region NR and the PMOS region PR may be disposed, and a plurality of substrate pad regions 3 may be disposed, mainly in an edge region. When the substrate pad regions 3 include the well region, the substrate pad regions 3 may be disposed in the well region 5, and may be high concentration doping regions.

The element isolating layers 21 may define active regions in the substrate 1. The element isolating layers 21 may be disposed respectively in the NMOS region NR and the PMOS region PR, and, when the NMOS region NR and/or the PMOS region PR include the well region 5, the NMOS region NR and/or the PMOS region PR may be disposed to define active regions of each transistor in the well region 5. The element isolating layers 21 may be formed, for example, in a shallow trench isolation (STI) process. In some implementations, the arrangement shape and depth of the element isolating layers 21 may be variously changed. The element isolating layers 21 may be formed of an insulating material. The element isolating layer 21 may be, for example, an oxide, a nitride, or combinations thereof.

In the NMOS region NR, the first circuit elements TR_{N} may be arranged in a matrix. The first circuit elements TR_{N} may be disposed on the upper surface Sf of the substrate 1 and may include planar transistors. Each of the first circuit elements TR_{N} may include a first gate structure GS_{N} including a first gate electrode structure GEN and a first gate dielectric layer 20, first source/drain regions D_{N} and S_{N}, and first gate spacers 40.

Stack structures of gate structures GS_{N} and GS_{P} of the first circuit elements TR_{N} and the second circuit elements TR_{P} may be identical to each other.

The first circuit elements TR_{N} may include the first gate structure GS_{N} having a first height h1 from the upper surface Sf of the substrate 1 as planar transistors.

The first gate structure GS_{N} may include the first gate electrode structure GEN having a first width Wg in the X-direction and having a first length L1 in the Y-direction, and including the first gate dielectric layer 20, a lower conductive layer 35, and an upper conductive layer 37.

The first gate dielectric layer 20 may include a low-K material, such as an oxide or a nitride, and may include, preferably, a silicon oxide film (SiO₂). The first gate dielectric layer 20 may have a first thickness T1, and the first thickness T1 may be about 40 nm to 50 nm, but the present disclosure is not limited thereto.

The first gate electrode structure GEN may be disposed on the first gate dielectric layer 20, and may include at least a double layer, but the present disclosure is not limited thereto. The gate electrode structure GEN may include the lower conductive layer 35 and an upper conductive layer 37.

The lower conductive layer 35 may include polysilicon, but the present disclosure is not limited thereto, and the upper conductive layer 37 may include a metal such as tungsten or aluminum. An ohmic contact layer 38 may be further included between the upper and lower conductive layers 35 and 37, and the ohmic contact layer 38 may include titanium nitride (TiN), and tantalum nitride (TaN), but the present disclosure is not limited thereto. The ohmic contact layer 38 may have a thickness significantly smaller than thicknesses of the lower conductive layer 35 and the upper conductive layer 37.

A mask layer 39 may be further included on an upper portion of the gate electrode structure GEN. The mask layer 39 may include silicon nitride, and silicon oxynitride.

The gate spacers 40 may be disposed on both side surfaces of the first gate structure GS_{N} in the Y-direction. The gate spacers 40 may be formed of at least one of oxide, nitride, or oxynitride, and may be formed of a low-K film.

The first source/drain regions D_{N} and S_{N} may be disposed on the upper surface Sf of the substrate 1 on both sides of the gate structure GS_{N} in the Y-direction. The first source/drain regions D_{N} and S_{N} may be disposed on both sides of the first gate structure GS_{N} in the Y-direction from the upper surface Sf of the substrate 1 to a first depth d1 inwardly, simultaneously with including impurities. The first source/drain regions D_{N} and S_{N} may have a second width Wd in the X-direction, and the second width Wd may be equal to or smaller than the first width Wg of the first gate structure GS_{N}, and may be included in the first width Wg. Accordingly, the first source/drain regions D_{N} and S_{N} may be aligned with the first gate structure GS_{N} in the Y-direction.

Each of the first source/drain regions D_{N} and S_{N} may include a low concentration doping region 2 and a high concentration doping region 4. The low concentration doping region 2 may be disposed to be offset from the first gate structure GS_{N} in the Z-direction, and may be doped with low concentration impurities by the first depth d1. The first depth d1 may satisfy a length of about 40 nm to 50 nm. The high concentration doping region 4 may be doped at a depth shallower than the first depth d1 of the low concentration doping region 2, and a depth of the high concentration doping region 4 may be 10 nm to 12 nm, but the present disclosure is not limited thereto.

The low concentration doping region 2 and the high concentration doping region 4 in the first source regions S_{N} are doped with impurities of the same conductivity type, and only doping concentrations thereof may be different from each other. The high concentration doping region 4 may have an area smaller than an area of the low concentration doping region 2, and the high concentration doping region 4 may be spaced apart from the first gate structure GS_{N} so as not to overlap the first gate structure GS_{N} on an X-Y plane. Accordingly, the high concentration doping region 4 may function substantially as the first source regions S_{N}, and the low concentration doping region 2 may be a diffusion region of the high concentration doping region 4, but the present disclosure is not limited thereto.

The low concentration doping region 2 and the high concentration doping region 4 in the first drain regions D_{N} are doped with impurities of the same conductivity type, and only doping concentrations thereof may be different from each other. The high concentration doping region 4 may have an area smaller than an area of the low concentration doping region 2, and the high concentration doping region 4 and the low concentration doping region 2 may be spaced apart from the first gate structure GS_{N} so as not to overlap the first gate structure GS_{N} on the X-Y plane. The low concentration doping region 2 may have the first depth d1 like the low concentration doping region 2 of the first source regions S_{N}, and the high concentration doping region 4 may also be doped at a shallower depth than the low concentration doping region 2. Accordingly, the high concentration doping region 4 functions substantially as the drain region, and the low concentration doping region 2 may be a diffusion region of the high concentration doping region 4, but the present disclosure is not limited thereto.

The doping concentrations of the high concentration doping regions 4 of each of the first source/drain regions D_{N} and S_{N} may be identical to each other, and the doping concentrations of the low concentration doping regions 2 may be identical to each other, but the present disclosure is not limited thereto. Additionally, a separation distance between the high concentration doping regions 4 may be greater than a separation distance between the low concentration doping regions 2, and the separation distance between the low concentration doping regions 2 may be substantially identical to the first length L1 of the first gate structure GS_{N}, may be defined as a channel length, and may be about 1 μm to 1.2 μm, but the present disclosure is not limited thereto. The first depth d1 of the low concentration doping regions 4 may have a depth shallower than a depth of the element isolating layers 21.

A channel region ACT_{N} may be disposed in the substrate 1 from the upper surface Sf of the substrate 1 below the first gate structure GS between the first source/drain regions D_{N} and S_{N}. Depending on the magnitude of the gate voltage applied to the first gate structure GS_{N}, a region in which the inversion layer is formed may be regarded as the channel region ACT_{N}.

Meanwhile, each of the first circuit elements TR_{N} may include a separation trench structure 30 between a lower portion of the channel region ACT_{N} and the first drain region D_{N}.

The separation trench structure 30 may extend in the Z-direction from the lower surface Sr of the substrate 1 toward a boundary between the low concentration doping region 2 of the first drain region D_{N} and the channel region ACT_{N}, and may extend in the X-direction to have a length L2 equal to or greater than the second width Wd of the first drain region D_{N} in the X-direction, as illustrated in FIG. 1 and FIG. 2.

The separation trench structure 30 having a length equal to or greater than the first drain region D_{N} may be defined as extending along an edge of the first drain region D_{N} in the X-direction so as to overlap all the boundaries between the first drain region D_{N} and the channel region ACT_{N}. Accordingly, the separation trench structure 30 may have a length equal to or greater than the second width Wd in the X-direction, and may have an upper surface width W1 in the Y-direction, and a first sub-width W3 of the upper surface width W1 may be disposed so as to overlap the channel region ACT_{N} and a second sub-width W4 may be disposed to overlap the first drain region D_{N}. The upper surface width W1 may satisfy about 100 nm or less, and may satisfy, for example, 1/10 or less of the first length L1 of the first gate structure GS_{N}.

The separation trench structure 30 has a shape like a wall extending from the lower surface Sr of the substrate 1 in the Z-direction, and may be disposed to have a separation distance so that the separation trench structure 30 may be spaced apart from the upper surface Sf of the substrate 1 by a second distance d2. Accordingly, an upper surface of the separation trench structure 30 may be disposed at a level lower than the upper surface Sf of the substrate 1 by the second distance d2, and a lower surface of the separation trench structure 30 may be a coplanar with the lower surface Sr of the substrate 1. The second distance d2 may be equal to or greater than the thickness of the inversion layer of the channel region ACT_{N}, and may be, for example, about 9 nm to 11 nm, preferably about 10 nm. The upper surface of the separation trench structure 30 may be considered to be disposed at a level between the upper surface Sf of the substrate 1 and a lower surface of the first drain region D_{N}.

Accordingly, the separation trench structure 30 may extend from a point spaced apart from the upper surface Sf of the substrate 1 by a channel depth to the lower surface Sr of the substrate 1, and may physically and electrically separate the substrate 1 of a lower portion of the channel region ACT_{N} below the channel region ACT_{N} from the first drain region D_{N} at the same time.

The separation trench structure 30 may include an insulating material, and may include silicon oxide, silicon nitride, silicon oxynitride, and silicon carbonitride, and may also include a high-K material. The high-K material may refer to a dielectric material having a higher dielectric constant than silicon oxide (SiO₂), and may include at least one of hafnium oxide, hafnium silicon oxide, zirconium oxide, zirconium silicon oxide, tantalum oxide, titanium oxide, barium titanium oxide, lithium oxide, aluminum oxide, or lead zinc niobate. The separation trench structure 30 may be applied to any insulating material that may block a movement of carriers from the first drain region D_{N} to the source region S_{N} through the substrate 1 of the lower portion of the channel region ACT_{N}.

The separation trench structure 30 may include a first portion dividing the upper surface width W1 of an upper surface thereof in the X-direction and overlapping the channel region ACT_{N}, and a second portion overlapping the first drain region D_{N}, and the first sub-width W3 of the upper surface of the first portion may be equal to or greater than the second sub-width W4 of an upper surface of the second portion.

Accordingly, the first portion of the separation trench structure 30 may include a first side surface Ss bent from the upper surface and facing the first source region S_{N}, and the first portion may have both the upper surface and the first side surface Ss in direct contact with the substrate 1. Accordingly, the first portion may be disposed across the substrate 1 from a lower surface to the upper surface of the first portion. The second portion of the separation trench structure 30 may include a second side surface Sd connected to the first portion in the Y-direction and bent from an upper surface thereof to face the first drain region D_{N}. The second portion of the separation trench structures 30 may have an upper surface in contact with the low concentration doping region 2 of the first drain region D_{N}, and an upper region of the second side surface Sd bent from the upper surface may be in contact with the low concentration doping region 2 of the first drain region D_{N}, and a lower region of the second side surface Sd may be in contact with the substrate 1. The second portion may be formed without being bent, but the present disclosure is not limited thereto, and the low concentration doping region 2 of the first drain region D_{N} may have a concave step portion (e.g., a corner 33 as illustrated in FIG. 3A) in an edge connected from a lower end to a side surface by the second portion. A depth of the step portion may be about 30 nm to 40 nm, but the present disclosure is not limited thereto.

In this manner, the separation trench structures 30 may be disposed to penetrate through a region of the lower substrate 1 of the channel region ACT_{N} contacting the first drain region D_{N} and a peripheral region thereof between the low concentration doping region 2 of the first drain region D_{N} and the channel region ACT_{N}, so that the first drain region D_{N} may be physically and electrically separated from the lower substrate 1 of the channel region ACT_{N} except an upper region of the channel region ACT_{N}.

When the first circuit elements TR_{N} are driven by a high voltage of several to several tens of volts, a drain voltage applied to the first drain region D_{N} may be a high voltage of several volts, for example, 10 to 30 V, and a gate voltage may also be a high voltage of several tens of volts. Such a high drain voltage of the first drain region D_{N} may forms a deep depletion region below the first drain region D_{N}, and the deep depletion region may be expanded to the lower portion of the channel region ACT_{N} and may be connected to the first source region S_{N}, which may cause undesired punch through. Specifically, in a case of an off state, that is, even when there is no gate voltage in the channel region ACT_{N}, current may flow through the substrate 1 of the lower portion of the channel region ACT_{N}, and an extremely large off current may be formed, which may deteriorate the reliability of the device.

In one or more implementations, in a high-voltage element, separation trench structures 30 that block a space between the first drain region D_{N} and the channel region ACT_{N} below an upper portion of the channel region ACT_{N} may be disposed in the first circuit elements TR_{N}, which are NMOS transistors, thereby eliminating the punch through. Specifically, a depletion region may be prevented from being expanded along the lower portion of the channel region ACT_{N} from the lower portion of the first drain region D_{N} by the separation trench structures 30, and accordingly, a leakage current flowing through the lower substrate 1 of the channel region ACT_{N} other than the channel region ACT_{N} may be minimized.

Accordingly, carriers from the first drain region D_{N} may flow only through the upper portion of the channel region ACT_{N}, and the upper portion of the channel region ACT_{N} may form an inversion layer only when the gate voltage is applied, thereby minimizing the off current.

The separation trench structures 30 may be formed to penetrate through the substrate 1 in a direction, perpendicular to the upper surface Sf of the substrate 1, from the lower surface Sr of the substrate 1 toward the upper surface Sf of the substrate 1, while being spaced apart from the upper surface Sf of the substrate 1 by the second distance d2, thereby physically defining the channel region ACT_{N}. A width of a lower surface of the separation trench structures 30 may be identical to or different from the upper surface width W1, but the present disclosure is not limited thereto.

Meanwhile, the second circuit elements TR_{P} may be arranged in a matrix in the PMOS region PR, and the second circuit elements TR_{P} may include planar transistors in the well region 5 of the substrate 1, that is, the well region 5 including the first conductive impurities. The first conductive impurities may be N-type impurities, and the second circuit elements TR_{P} may be PMOS transistors.

Each of the second circuit elements TR_{P} may have the same gate structure as the first circuit elements TR_{N}.

Specifically, the second gate structure GS_{P} may include a second gate electrode structure GE_{P} including the gate dielectric layer 20, the lower conductive layer 35 and the upper conductive layer 37, and the mask layer 39, which are identical to those of the first circuit elements TR_{N}. The configurations of each of the gate dielectric layer 20, the lower conductive layer 35, the upper conductive layer 37, the mask layer 39 and the ohmic contact layer 38 may be identical to those of the first gate structure GS_{N}.

The gate spacers 40 may be disposed on both side surfaces of the second gate structure GS_{P}. The second source/drain regions D_{P} and S_{P} may be disposed on an upper surface of the substrate 1 on both sides of the second gate structure GS_{P}.

The gate spacers 40 may be formed of at least one of an oxide, a nitride, or an oxynitride, and may be formed of, for example, a low-K film.

The second source/drain regions D_{P} and S_{P} may be disposed on both sides of the second gate structure GS_{P} from the upper surface of the substrate 1 to the first depth d1 inwardly, simultaneously with including impurities.

The second source/drain regions D_{P} and S_{P} may include the low concentration doping region 2 and the high concentration doping region 4, respectively. The low concentration doping region 2 may be disposed to be offset from the gate structure GS_{P} in the Z-direction, and may be doped with low concentration impurities by the first depth d1. The first depth d1 may satisfy a length of 40 nm to 50 nm, and the high concentration doping region 4 may be shallower than the first depth d1 of the low concentration doping region 2, and may be, for example, about 10 nm to 12 nm, but the present disclosure is not limited thereto.

The low concentration doping region 2 and the high concentration doping region 4 in the second source/drain regions D_{P} and S_{P} may be doped with impurities of the same conductivity type, and only doping concentrations of the impurities may be different from each other. The high concentration doping region 4 may have an area smaller than an area of the low concentration doping region 2, and the high concentration doping region 4 and the low concentration doping region 2 may be disposed so as not to overlap the gate structure GS_{P} on the X-Y plane. Accordingly, the high concentration doping region 4 functions substantially as the source region, and the low concentration doping region 2 may be a diffusion region of the high concentration doping region 4, but the present disclosure is not limited thereto.

The second circuit elements TR_{P} may function as PMOS transistors in the substrate 1, and even if the second circuit elements TR_{P} are driven by a high-voltage element, the separation trench structures 30 may not be disposed. That is, in the case of the PMOS transistor, since a depletion region does not diffuse below the second drain region D_{P}, the separation trench structures 30 may not be required.

On the substrate 1, the first circuit elements TR_{N} may be disposed as NMOS transistors in the NMOS region NR, and the second circuit elements TR_{P} may be arranged as PMOS transistors in the PMOS region PR, and various circuits may be implemented through plugs and interconnections for electrical connection with the gate structures GS_{N} and GS_{P} and the source/drain regions D_{N}, S_{N}, D_{P} and S_{P}, respectively.

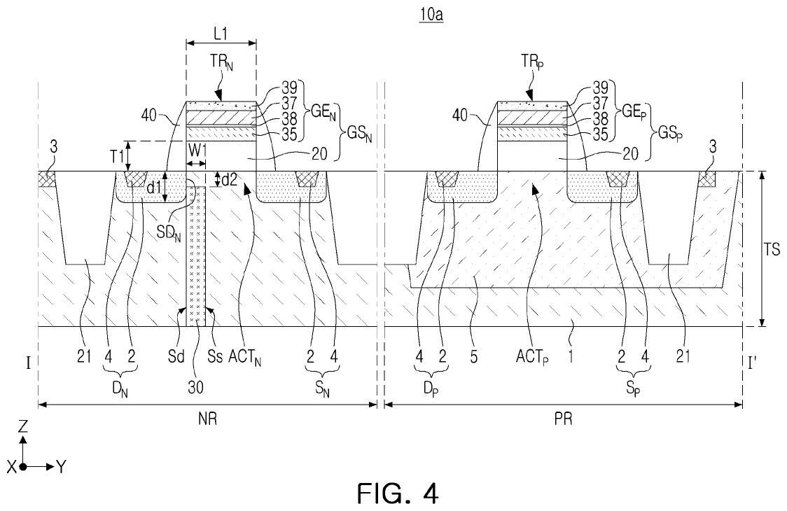

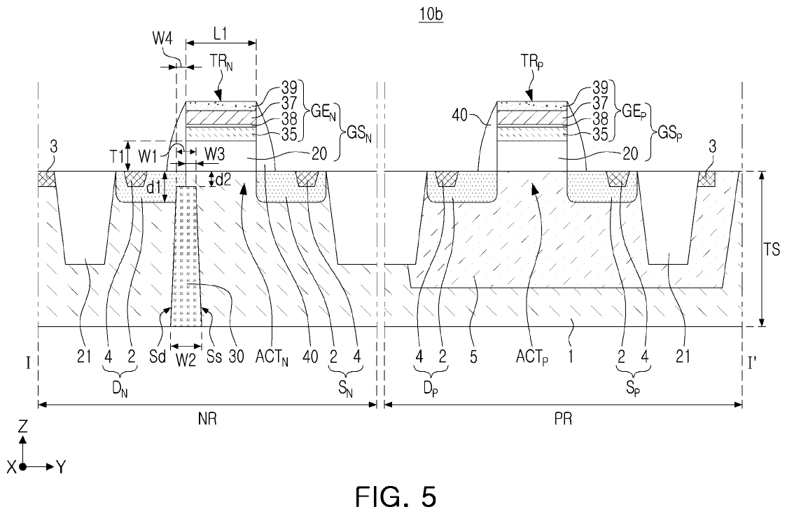

Hereinafter, example implementations will be described with reference to FIGS. 4 to 7. FIGS. 4 and 5 are schematic cross-sectional views of semiconductor devices according to one or more implementations.

Referring to FIG. 4, a semiconductor device 10a may be the same as the semiconductor device 10 of FIGS. 1 to 3D, except that the separation trench structures 30 are formed only of the first portion.

Each of the separation trench structures 30 of the semiconductor device 10a may have lower surfaces, coplanar with the lower surface Sr of the substrate 1, and may be disposed so that upper surfaces thereof may be spaced apart from the upper surface Sf of the substrate 1 by the second distance d2, by penetrating through the substrate 1 from the lower surface Sr of the substrate 1. The separation trench structures 30 may have a length L2 equal to or greater than the first source/drain region D_{N} and S_{N} in the Y-direction, and may have an upper surface width W1 from the upper surface in the X-direction. The separation trench structures 30 may include only a first portion overlapping the channel region ACT_{N} without a second portion overlapping the first drain region D_{N}. That is, the separation trench structures 30 may be disposed so that the first portion has an upper surface width W1 by shifting toward the channel region ACT_{N}.

The first portion of the separation trench structures 30 may include a first side surface Ss bent from the upper surface and facing the first source region S_{N} and a second side surface Sd bent from the upper surface and facing the first drain region D_{N}. In the first portion, both the upper surface and the first side surface Ss may be in direct contact with the substrate 1, and in the second side surface Sd, an upper region may be in contact with the low concentration doping region 2 of the first drain region D_{N}.

The first portion may be formed without being bent, and the second side surface Sd may be disposed to be in contact with an edge of the first drain region D_{N}, i.e., a side surface SD_{N}, so that the first drain region D_{N} may be formed without a step portion.

In this manner, the separation trench structure 30 may penetrate through the substrate 1 while contacting the edge and the side surface SD_{N} of the first drain region D_{N} between the low concentration doping region 2 of the first drain region D_{N} and the channel region ACT_{N}, and may extend to the lower portion of the channel region ACT_{N}, so that the first drain region D_{N} may be physically and electrically isolated from the substrate 1 of the lower portion of the channel region ACT_{N} except the upper region of the channel region ACT_{N}.

Referring to FIG. 5, a semiconductor device 10b may be the same as the semiconductor device 10 of FIGS. 1 to 3D, except that the separation trench structure 30 has an inclination.

Each of the separation trench structures 30 of the semiconductor device 10b may have lower surfaces, coplanar with the lower surface Sr of the substrate 1, and may be disposed so that upper surfaces thereof may be spaced apart from the upper surface Sf of the substrate 1 by the second distance d2, by penetrating through the substrate 1 from the lower surface Sr of the substrate 1.

In each of the separation trench structures 30, a width W2 of the lower surface thereof in the X-direction is greater than a width W1 of the upper surface, and for example, the width may gradually increase from the upper surface to the lower surface. Accordingly, the side surfaces Sd and Ss connecting the upper surface and the lower surface may have an inclination at least in some portions, and for example, may have a continuous inclination from the upper surface to the lower surface. The inclination of the side surface may also be applied to a length in the Y-direction, and it may be understood that an area thereof may increase toward the lower surface.

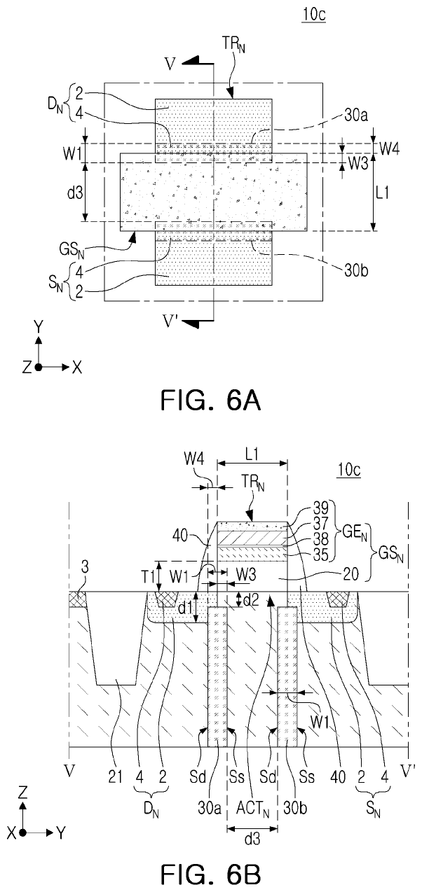

FIG. 6A is a plan view of a semiconductor device according to one or more implementations, and FIG. 6B is a cross-sectional view of the semiconductor device of FIG. 6A taken along line V-V′.

Referring to FIGS. 6A and 6B, a semiconductor device 10c may be the same as the semiconductor device 10 of FIGS. 1 to 3D, except that the separation trench structures 30 are additionally disposed between the first source region S_{N} and the channel region ACT_{N}.

The semiconductor device 10c may include first and second separation trench structures 30a and 30b, respectively.

Each of the first circuit elements TR_{N}, which are NMOS transistors of the semiconductor device 10c, may include the first separation trench structure 30a disposed between the first drain region D_{N} and the channel region ACT_{N}, and the second separation trench structure 30b disposed between the first source region S_{N} and the channel region ACT_{N}.

The first separation trench structure 30a and the second separation trench structure 30b may have the same shape. Since the first separation trench structure 30a has the same shape and arrangement as the separation trench structures 30 described in FIGS. 1 to 3D, a description thereof will be omitted.

The second separation trench structure 30b may also have a lower surface, coplanar with the lower surface Sr of the substrate 1, and may be disposed so that an upper surface thereof may be spaced apart from the upper surface Sf of the substrate 1 by the second distance d2, by penetrating through the substrate 1 from the lower surface Sr of the substrate 1. The second separation trench structure 30b may have a first portion and a second portion, and the first portion may penetrate through the substrate 1 below the channel region ACT_{N}, and the second portion adjacent to the first portion may penetrate through the first source region S_{N} in the upper region. That is, the first portion may include a first side surface Sd bent from the upper surface to contact the substrate 1 and facing the first drain region D_{N}, and the second portion may include a second side surface Ss bent from the upper surface to contact the first source region S_{N} in the upper region. Accordingly, the first source region S_{N} may have a concave step portion in a region bent from a lower end thereof to a side surface thereof by the second separation trench structure 30b. The step portion between the first source region S_{N} and the first drain region D_{N} may be symmetrical to each other, but the present disclosure is not limited thereto.

The side surfaces Ss and Sd of the first separation trench structure 30a and the second separation trench structure 30b may face each other with the substrate 1 interposed therebetween, and a separation distance d3 between the two first side surfaces Ss and Sd may be shorter than a channel length of the channel region ACT_{N}.

In this manner, the second separation trench structure 30b may penetrate through the substrate 1 to a lower region of the channel region ACT_{N} while contacting an edge of the first source region S_{N} between the low concentration doping region 2 of the first source region S_{N} and the channel region ACT_{N}, thereby blocking the leakage current flowing from the first drain region D_{N} from being injected into the first source region S_{N}.

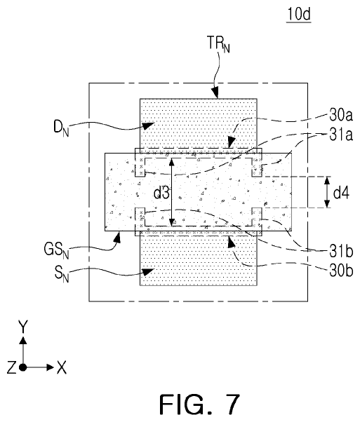

Referring to FIG. 7, a semiconductor device 10d may be the same as the semiconductor device 10c of FIG. 6A and FIG. 6B, except that the separation trench structures 30 include protruding regions.

Each of the first circuit elements TR_{N}, which are NMOS transistors of the semiconductor device 10d, may include a first separation trench structure 30a disposed between the first drain region D_{N} and the channel region ACT_{N}, and a second separation trench structure 30b disposed between the first source region S_{N} and the channel region ACT_{N}.

The first separation trench structure 30a and the second separation trench structure 30b may have the same shape. Each of the first and second separation trench structures 30a and 30b may include a base region and protruding regions 31a and 31b protruding from both ends of the base region toward the channel region ACT_{N}. The base region may be the same as the first and second separation trench structures 30a and 30b of the semiconductor device 10c of FIGS. 6A and 6B.

The first separation trench structure 30a may include two protruding regions 31a protruding in the Y-direction from the first side surface Ss toward the channel region ACT_{N} in both ends of the base region in the X-direction, i.e., a length direction, that, toward the second separation trench structure 30b.

The two protruding regions 31a may have the same width as that of the base region, and a protruding length thereof may be equal to or smaller than a width thereof. The protruding regions 31a may also extend in the Z-direction to have the same height as that of the base region.

The second separation trench structure 30b may include two protruding regions 31b protruding in the Y-direction from the first side surface Sd toward the channel region ACT_{N} in both ends of the basic region in the X-direction, i.e., the length direction, that is, toward the first separation trench structure 30a.

The two protruding regions 31b may have the same width as that of the base region, and a protruding length thereof may be equal to or smaller than a width thereof. The protruding regions 31b may also extend in the Z-direction to have the same height as that of the base region.

Accordingly, the protruding regions 31a and 31b of the first and second separation trench structures 30a and 30b may be spaced apart by a fourth distance d4 and may face each other. In this case, the fourth distance d4 may be less than the third distance d3, which is a separation distance between the base regions. Through a separation space of the fourth distance d3, a substrate body voltage applied from the substrate pad region 3 may be transmitted to a substrate region below the channel region ACT_{N}. When the first and second separation trench structures 30a and 30b include the protruding regions 31a and 31b, the leakage current flowing along an interface between the first drain region D_{N} and the element isolating layer 21 may be blocked.

The various first circuit elements TR_{N} and the various second circuit elements TR_{P} illustrated in FIGS. 1 to 7 are applicable to a circuit design of various semiconductor devices.

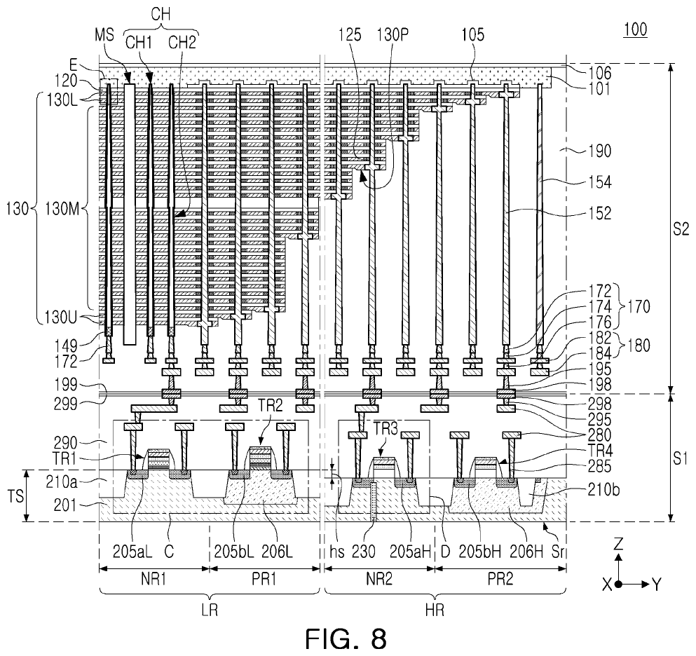

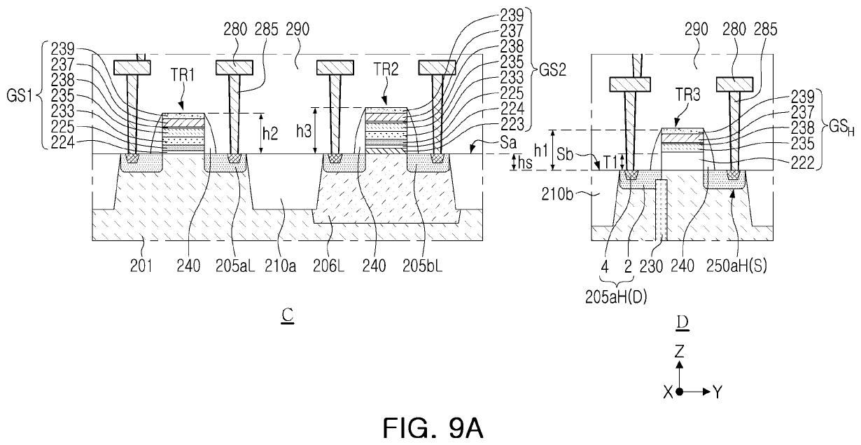

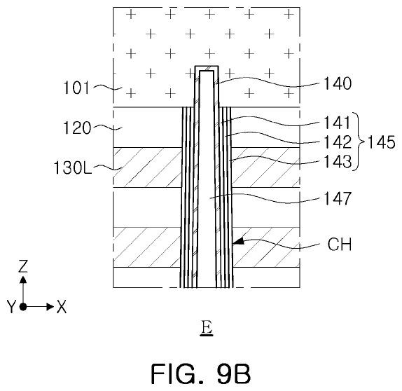

Hereinafter, with reference to FIGS. 8 to 9B, an example in which the semiconductor devices of FIGS. 1 to 5 are applied to a portion of the peripheral circuit structure of a memory device will be described.

FIGS. 8 to 9B illustrate a semiconductor device according to one or more implementations, FIG. 8 is a cross-sectional view of a semiconductor device according to one or more implementations, and FIGS. 9A and 9B are partially enlarged views of a semiconductor device according to one or more implementations of FIG. 6, and FIG. 9A illustrates portions “C” and “D” of FIG. 8, and FIG. 9B illustrates portion “E” of FIG. 8.

Referring to FIGS. 8 to 9B, a semiconductor device 100 includes first and second substrate structures S1 and S2 that are bonded to each other vertically. The first substrate structure S1 may include a peripheral circuit region, and the second substrate structure S2 may include a memory cell region.

The first substrate structure S1 may have a low voltage element region LR and a high voltage element region HR. The low voltage element region LR may be defined as a region in which circuit elements capable of being controlled with a relatively low driving voltage are disposed, and the high voltage element region HR may be defined as a region in which circuit elements capable of being controlled with a relatively high driving voltage are disposed.

The first substrate structure S1 may include a substrate 201, element isolating layers 210a and 210b in the substrate 201, first circuit elements TR1 and second circuit elements TR2 disposed on the substrate 201 in the low voltage element region LR, third circuit elements TR3 and fourth circuit elements TR4 disposed on the substrate 201 in the high voltage element region HR, a peripheral region insulating layer 290 on an upper surface of the substrate 201, contact plugs 285 on the substrate 201, circuit interconnection lines 280, first bonding vias 295, first bonding pads 298, and a first bonding insulating layer 299.

The first substrate structure S1 may include a first well region 206L, first and second source/drain regions 205aL and 205bL disposed in the low voltage element region LR, a second well region 206H disposed in the high voltage element region HR, and first and second source/drain regions 205aH and 205bH.

The substrate 201 may have upper surfaces Sa and Sb extending in the X-direction and the Y-direction, and a lower surface Sr opposite to the upper surfaces Sa and Sb.

The substrate 201 may include a first upper surface Sa disposed in the low voltage element region LR and a second upper surface Sb disposed in the high voltage element region HR, and the second upper surface Sb may be disposed at a level lower than a level of the first upper surface Sa by a substrate step portion hs in the Z-direction. Accordingly, a starting point of a gate structure GS_{H} of the high voltage element region HR may be disposed to be lower as a whole.

The substrate 201 may include a semiconductor material, such as a group IV semiconductor, a group III-V compound semiconductor, or a group II-VI compound semiconductor. For example, the substrate 201 may be provided as a single crystal silicon bulk wafer.

CMOS transistors may be disposed in each of the low voltage element region LR and the high voltage element region HR, and a first well region 206L and a second well region 206H may be disposed in the substrate 201 so that transistors of different conductivity types may be disposed in each element regions LR and HR. When the substrate 201 is a P-type semiconductor, the first well region 206L and the second well region 206H may be N-type wells doped with N-type impurities.

Accordingly, portions other than the first well region 206L and the second well region 206H may be defined as first element regions NR1 and NR2 in which the NMOS transistors are disposed, and portions in which the first well region 206L and the second well region 206H are disposed may be defined as second element regions PR1 and PR2 in which the PMOS transistors are disposed. When the conductivity types of the substrate 201 are opposite, the conductivity types of each region may be opposite.

The low voltage element region LR and the high voltage element region HR may define active regions by forming the element isolating layers 210a and 210b, respectively. The element isolating layers 210a and 210b may be formed, for example, in a shallow trench isolation (STI) process. In some implementations, the arrangement shape and depth of the element isolating layers 210a and 210b may be variously changed. The element isolating layers 210a and 210b may be formed of an insulating material. The element isolating layers 210a and 210b may be, for example, oxides, nitrides, or combinations thereof.

The first and second source/drain regions 205aL, 205bL, 205aH and 205bH including impurities may be disposed in portions of the active regions.

The low voltage element region LR may include the first element region NR1 and the second element region PR1, and the high voltage element region HR may include the element region NR2 and the second element region PR2.

Accordingly, the first and second source/drain regions 205aL and 205bL in the low voltage element region LR may be regions disposed in the first element region NR1 and the second element region PR1 and doped with impurities of different conductivity types, respectively, and the first and second source/drain regions 205aH and 205bH in the high voltage element region HR may be regions disposed in the first element region NR2 and the second element region PR2 and doped with impurities of different conductivity types, respectively.

First source/drain regions 206aL and 206aH in the first element regions NR1 and NR2 in the low voltage element region LR and the high voltage element region HR may be doped with the same impurities, and second source/drain regions 206bL and 206bH in the second element regions PR1 and PR2 in the low voltage element region LR and the high voltage element region HR may be doped with the same impurities.

In the first substrate structure S1 of the semiconductor device 100, the first element region NR2 and the second element region PR2 of the high voltage element region HR may correspond to the first element region NR and the second element region PR of the semiconductor device 10 of FIGS. 1 to 3D described above, respectively.

Accordingly, the first circuit element TR_{N}, which is an NMOS transistor of FIGS. 1 to 3D, may be the third circuit element TR3 of the high-voltage element region HR, and the second circuit element TR_{P}, which is a PMOS transistor of FIGS. 1 to 3D, may be the fourth circuit element TR4 of the high-voltage element region HR.

The first circuit elements TR1 of the low-voltage element region LR may be disposed on an upper surface of the substrate 201, and may be planar transistors and may include a first gate structure GS1 including first gate dielectric structures 224 and 225N and first gate electrode layers 232, 235, 238 and 237, first source/drain regions 205aL, and first gate spacers 240.

The first gate dielectric structures 224 and 225 may include the first interface insulating layer 224 and a first gate dielectric layer 225.

The first interface insulating layer 224 may be disposed on the first upper surface Sa of the substrate 201 and may include silicon oxide having a low-K dielectric constant, and the first gate dielectric layer 225 may include a high-k dielectric material. The high-K dielectric material may refer to a dielectric material having a higher dielectric constant than a silicon oxide film (SiO₂). The first gate dielectric layer 225 may include at least one of hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, or lead zinc niobate.

The first gate electrode layers 232, 235, 238 and 237 may be disposed on the first gate dielectric layer 225.

The first gate electrode layers 232, 235, 238 and 237 may include at least a double layer, but the present disclosure is not limited thereto. The first gate electrode layers 232, 235, 238 and 237 may include a first conductive layer 233, a second conductive layer 235, and a third conductive layer 237, which are stacked in a vertical direction.

The first conductive layer 232 is a metal base layer and may include a metal or a metal nitride. The first conductive layer 232 may include tungsten, titanium nitride, tantalum nitride, titanium silicon nitride (TiSiN), silicon-doped titanium nitride (Si-doped TIN, TSN), or combinations thereof. The first conductive layer 232 may preferably include titanium nitride (TiN) or TSN (Ti—Si—N).

The second conductive layer 233 may include polysilicon, but the present disclosure is not limited thereto. The third conductive layer 237 may include a metal material different from the first conductive layer 232, and may include, for example, tungsten (W), but the present disclosure is not limited thereto.

An ohmic contact layer 238 may be further included between the second conductive layer 233 and the third conductive layer 237, and the ohmic contact layer 238 may include titanium nitride (TiN), tantalum nitride (TaN), but is not limited thereto. The ohmic contact layer 238 may have a thickness significantly smaller than thicknesses of the second conductive layer 233 and the third conductive layer 237.

A mask layer 239 may be further included in upper portions of the first gate electrode layers 232, 235, 238 and 237. The mask layer 239 may include silicon nitride, and silicon oxynitride. A vertical length from an upper surface of the first gate structure GS1 to the substrate 201 may have a second height h2.

The first gate spacers 240 may be disposed on both side surfaces of the first gate structure GS1. The first gate spacers 240 may insulate the first source/drain regions 205aL from the first gate structure GS1. The first gate spacers 240 may be formed of at least one of an oxide, a nitride, or an oxynitride, and may be made of, for example, a low-K film.

The first source/drain regions 205aL may be disposed in the substrate 201 on both sides of the first gate structure GS1. The first source/drain regions 205aL may include a plurality of impurity regions having different doping concentrations, and may include the high concentration doping region 4 and the low concentration doping region 2, respectively.

The second circuit elements TR2 of the low voltage element region LR may be PMOS transistors as planar transistors in the well region 206L of the substrate 201.

Each of the second circuit elements TR2 may include a channel structure 223, second gate dielectric structures 224 and 225, a second gate structure GS2 including second gate electrode layers, second source/drain regions 205bL, and gate spacers 240.

The channel structure 223 may include a semiconductor material having a band gap smaller than a band gap of the substrate 201 on the first upper surface Sa of the substrate 201. For example, when the substrate 201 includes silicon, the channel structure may include silicon-germanium (SiGe).

The second gate dielectric structures 224 and 225 may include a second interface insulating layer 224 and a second gate dielectric layer 225, and may be identical to the second interface insulating layer 224 and the first gate dielectric layer 225 of the first gate dielectric structures 224 and 225, respectively, but the present disclosure is not limited thereto.

The second gate electrode layers 232, 235, 238 and 237 may be disposed on the second gate dielectric layer 225.

The second gate electrode layers 232, 235, 238 and 237 may include at least a double layer, but the present disclosure is not limited thereto. The second gate electrode layers 232, 235, 238 and 237 may include a first conductive layer 233, a second conductive layer 235, and a third conductive layer 237, which are stacked in the vertical direction. The second gate electrode layers 232, 235, 238 and 237 may correspond to each layer of the first gate electrode layers 232, 235, 238 and 237, and a description thereof is omitted.

A mask layer 239 may further be included in upper portions of the second gate electrode layers 232, 235, 238 and 237. The mask layer 239 may include silicon nitride, and silicon oxynitride. The second gate structure GS2 may have a third height h3, and the third height h3 may be greater than the second height h2 of the first gate structure GS1.

The second gate spacers 240 may be disposed on both side surfaces of the second gate structure GS_{P}. The second source/drain regions 205bL may be disposed in the first well region 206L of the substrate 201 on both sides of the second gate structure GS2.

Meanwhile, third circuit elements TR3 and fourth circuit elements TR4 may be further disposed in the high voltage element region HR of the semiconductor device 100.

The third circuit elements TR3 may function as NMOS transistors in the second upper surface Sb of the high voltage element region HR, and the fourth circuit elements TR4 may function as PMOS transistors in the second upper surface Sb of the high voltage element region HR.

In FIGS. 8 and 9A, sizes of the circuit elements TR3 and TR4 in the high voltage element region HR, for example, a channel length, or the like, are illustrated as being identical or similar to those of the circuit elements TR1 and TR2 in the low voltage element region LR, but the present disclosure is not limited thereto, and the sizes of the circuit elements TR3 and TR4 in the high voltage element region HR, for example, the channel length, or the like, may be greater than those of the circuit elements TR1 and TR2.

The third circuit elements TR3 and the fourth circuit elements TR4 may be disposed in respective conductive regions thereof, and at least one may be disposed in the well region 206H. In FIG. 8, it is illustrated that the substrate 201 is a P-type substrate 201 and the fourth circuit elements TR4 are disposed in the well region 206H doped with N-type impurities, but the present disclosure is not limited thereto.

The third circuit elements TR3 and the fourth circuit elements TR4 may have the same stack structure of the gate structure GS_{H} except that regions in which third circuit elements TR3 and the fourth circuit elements TR4 are disposed are of different conductive types.

That is, the third circuit elements TR3 and the fourth circuit elements TR4 are planar transistors and may include the gate structure GS_{H} having a first height h1 from the substrate 201 on a second upper surface Sb that is lower than the first upper surface Sa of the substrate 201 by the substrate step portion hs, and the gate spacer 240, and the third and fourth source/drain regions 205aH and 205bH.

The gate structure GS_{H} may include the gate dielectric layer 222, the lower conductive layer 235, and the upper conductive layer 237.

The gate dielectric layer 222 may include a low-K material, such as an oxide or a nitride, and may include, preferably, a silicon oxide film (SiO₂). The gate dielectric layer 222 may have a thickness T1 greater than a thickness of the interface insulating layer 224 of the first circuit element TR1 and the second circuit element TR2 or a thickness of the first and second gate dielectric layers 225, and may preferably have a thickness substantially equal to the substrate step portion hs, but the present disclosure is not limited thereto.

The gate electrode layers 235, 238 and 237 may be disposed on the gate dielectric layer 222, and may include at least a double player, but is not limited thereto. The gate electrode layers 235, 238 and 237 may include a lower conductive layer 235 and an upper conductive layer 237. The lower conductive layer 235 may include polysilicon, but the present disclosure is not limited thereto, and may be formed of substantially the same material and the same thickness as the second conductive layer 235 of the second circuit element TR2. The upper conductive layer 237 may include a metal such as tungsten or aluminum, and may be formed of substantially the same material and the same thickness as the third conductive layer 237 of the second circuit element TR2. An ohmic contact layer 238 may be further included between the upper and lower conductive layers 235 and 237, and the ohmic contact layer 238 may include titanium nitride (TiN) or tantalum nitride (TaN), but is not limited thereto. The ohmic contact layer 238 may have a thickness significantly smaller than thicknesses of the lower conductive layer 235 and the upper conductive layer 237.

A mask layer 239 may be further included in upper portions of the gate electrode layers 235, 238 and 237. The mask layer 239 may include silicon nitride, or silicon oxynitride.

Accordingly, in the third and fourth circuit elements TR3 and TR4, the upper conductive layer 235, the ohmic contact layer 238, the upper conductive layer 237, and the mask layer 239 may be disposed on the first upper surface Sa of the substrate 201, and a level of upper surfaces of the third and fourth circuit elements TR3 and TR4 may be disposed to be lower than a level of upper surfaces of the first circuit element TR1 and the second circuit element TR2.

However, the first upper surface Sa and the second upper surface Sb of the substrate 201 are not essential, and the low voltage element region LR and the high voltage element region HR may be disposed on the upper surfaces at the same level.

The gate spacers 240 may be disposed on both side surfaces of the gate structure GS_{H}. The gate spacers 240 may be formed of at least one of an oxide, a nitride, or an oxynitride, and may be formed of, for example, a low-K film.

The third and fourth source/drain regions 205aH and 205bH may be disposed on both sides of the gate structure GS_{H} while including impurities in the substrate 201.

Each of the third and fourth source/drain regions 205aH and 205bH include a source region S and a drain region D, and the source region S and the drain region D may include a low concentration doping region 2 and a high concentration doping region 4, respectively, and configurations thereof may be the same as those in FIGS. 1 to 3D.

In the semiconductor device 100 which is a memory device of FIG. 8, each of the third circuit elements TR3 of the high voltage element region HR, i.e., NMOS transistors, may include separation trench structures 230 between a third drain region 205aH(D) and the channel region ACT_{N}.

The separation trench structures 230 may have the same configuration as the separation trench structures 30 of FIGS. 1 to 3D, and extends in the Z-direction from the lower surface Sr of the substrate 201 toward a boundary between the low concentration doping region 2 of the third drain region 205aH(D) and the channel region ACT_{N}, which extends to have a length equal to or greater than an entire length of the third drain region 205aH(D).

The separation trench structures 230 have an upper surface width W1, and a first portion of the upper surface width W1 may be disposed to overlap the third drain region 205aH(D), and a second portion thereof may be arranged to overlap the channel region ACT_{N}.

The separation trench structures 230 may be formed to have a shape like a wall extending in the Z-direction from the lower surface Sr of the substrate 201, and may be formed to have a separation distance so that the separation trench structures 230 are spaced apart from the second upper surface Sb of the substrate 201 by the second distance d2. Accordingly, upper surfaces of the separation trench structures 230 may be disposed at a level lower than a level of the second upper surface Sb of the substrate 201 by the second distance d2, and the surfaces of the separation trench structures 230 may be coplanar with the lower surface Sr of the substrate 201. The second distance d2 may be defined as a channel depth of 9 nm to 11 nm, preferably about 10 nm.

Accordingly, the separation trench structures 230 may extend from a point spaced apart from the second upper surface Sb of the substrate 201 by the channel depth to the lower surface Sr of the substrate 201, and may physically and electrically separate the substrate 201 from the third drain region 205aH(D) in the lower portion of the channel region ACT_{N} at the same time.

The separation trench structures 230 may include insulating materials, and may include silicon oxide or silicon nitride.

The semiconductor device 100 of FIG. 8 is illustrated to have the separation trench structures 230 disposed therein for separating the third drain region 205aH(D) and the substrate 201 in the lower portion of the channel region ACT_{N} by corresponding to each of the NMOS transistors in the high voltage region, and a high voltage drain voltage may not be applied to the fourth circuit elements TR4, which are PMOS transistors in the high voltage element region HR, or the first and second circuit elements TR1 and TR2 in the low voltage element region LR, so that the separation trench structures 230 of the present disclosure may not be disposed.

Interconnection structures and a lower surface insulating layer may be further disposed on the lower surface of the substrate 201, and at least portions of the lower surface interconnection structures may form a back side power delivery network (BSPDN), but the present is not limited thereto. A passivation may be disposed to cover the lower surface Sr of the substrate 201 and the lower surface of the separation trench structures 230.

Meanwhile, the peripheral region insulating layer 290 on the upper surfaces Sa and Sb of the substrate 201 may be disposed on the first to fourth circuit elements TR1 to TR4. The peripheral region insulating layer 290 may include a plurality of insulating layers formed in different process operations. The peripheral region insulating layer 290 may be formed of an insulating material, and may include, for example, at least one of an oxide, a nitride, or an oxynitride.

The contact plugs 285 may penetrate through the peripheral region insulating layer 290 and may be connected to the high concentration doping regions 2 of the first to fourth source/drain regions 205aL, 205bL, 205aH and 205bH. Portions of the contact plugs 285 may penetrate through the peripheral region insulating layer 290 and may be connected to the gate structures.

Each of the contact plugs 285 may have an inclined side surface so that a width of an upper surface thereof is greater than a width of a lower surface thereof. Upper ends of the contact plugs 285 may be disposed at substantially the same level, but the present disclosure is not limited thereto.

Each of the contact plugs 285 may have a cylindrical shape. The contact plugs 285 may include a conductive material, and may include, for example, a semiconductor material, a metal-semiconductor compound, or at least one of a metal material such as tungsten (W), cobalt (Co), molybdenum (Mo), copper (Cu), ruthenium (Ru), or aluminum (Al), each of which may further include a diffusion barrier. The contact plugs 285 and the circuit interconnection lines 280 may be disposed on the upper surfaces Sa and Sb of the substrate 201 and may be connected to each other.

The first bonding vias 295, the first bonding pads 298, and the first bonding insulating layer 299 may be included in a first bonding structure, and may be disposed on uppermost circuit interconnection lines 280. The first bonding vias 295 may have a cylindrical shape, and the first bonding pads 298 may have a line shape. Upper surfaces of the first bonding pads 298 and an upper surface of the first bonding insulating layer 299 may be exposed to an upper surface of the first substrate structure S1. The first bonding vias 295 and the first bonding pads 298 may provide an electrical connection path between the first substrate structure S1 and the second substrate structure S2. Portions of the first bonding pads 298 may not be connected to the circuit interconnection line 280 in a lower portion and may be disposed only for bonding. The first bonding vias 295 and the first bonding pads 298 may include a conductive material, for example, copper (Cu). The first bonding insulating layer 299 may be disposed around the first bonding pads 298. The first bonding insulating layer 299 may also function as a diffusion barrier layer of the first bonding pads 298, and may include, for example, at least one of SiN, SiON, SiCN, SiOC, SiOCN, or SiO₂.

The second substrate structure S2 may include a plate layer 101, gate electrodes 130 stacked on a lower surface of the plate layer 101, interlayer insulating layers 120 alternately stacked with the gate electrodes 130, channel structures CH penetrating through the gate electrodes 130, a separation region MS penetrating through the gate electrodes 130 and extending in one direction, first cell contact plugs 152 connected to the gate electrodes 130, and a second cell contact plug 154 electrically connected to the plate layer 101. The second substrate structure S2 may further include a cover insulating layer 105, a passivation layer 106, contact insulating layers 125, cell upper contacts 170, cell interconnection lines 180, and cell region insulating layers 190. The second substrate structure S2 may further include second bonding vias 195, second bonding pads 198, and a second bonding insulating layer 199, as a second bonding structure.

The plate layer 101 may have an upper surface extending in the X-direction and the Y-direction. The plate layer 101 may function as a common source line of the semiconductor device 100. The plate layer 101 may include a conductive material. For example, the plate layer 101 may include a semiconductor material, such as a group IV semiconductor, a group III-V compound semiconductor, or a group II-VI compound semiconductor. For example, the group IV semiconductor may include silicon, germanium, or silicon-germanium. The plate layer 101 may further include impurities. The plate layer 101 may be provided as a polycrystalline semiconductor layer, such as a polycrystalline silicon layer, or an epitaxial layer. In some example implementations, the plate layer 101 may include a plurality of vertically stacked conductive layers.

The gate electrodes 130 may be vertically spaced apart from each other and stacked on the lower surface of the plate layer 101, thus forming a stack structure together with the interlayer insulating layers 120. The stack structure may include lower and upper stack structures vertically stacked and surrounding first and second channel structures CH1 and CH2, respectively. However, according to one or more implementations, the stack structure may be formed as a single stack structure.

The gate electrodes 130 may include at least one lower gate electrode 130L included in a gate of a ground select transistor, memory gate electrodes 130M included in a plurality of memory cells, and upper gate electrodes 130U included in gates of string select transistors. Here, the lower and upper stack structures, the lower gate electrode 130L, and the upper gate electrodes 130U may be referred to as “lower” and “upper” based on a direction during a manufacturing process. The number of memory gate electrodes 130M included in the memory cells may be determined according to the capacity of the semiconductor device 100. According to one or more example implementations, the number of upper and lower gate electrodes 130U and 130L may be 1 to 4 or more, respectively, and may have a structure identical to or different from the memory gate electrodes 130M. In some implementations, the gate electrodes 130 may further include a gate electrode 130 disposed below the upper gate electrodes 130U and/or on the lower gate electrode 130L and included in an erase transistor used for an erase operation utilizing the Gate Induced Drain Leakage (GIDL) phenomenon. Additionally, portions of the gate electrodes 130, for example, memory gate electrodes 130M adjacent to the upper or lower gate electrodes 130U and 130L, may be dummy gate electrodes.

The gate electrodes 130 may be vertically stacked and spaced apart from each other, and may extend by different lengths in at least one direction, for example, the X-direction, thus forming a staircase-type stepped structure. The gate electrodes 130 may also be disposed to have a stepped structure with each other in the Y-direction. By the stepped structure, the gate electrodes 130 may be configured so that the upper gate electrode 130 extends to be longer than the lower gate electrode 130, each of which may have regions in which lower surfaces thereof are exposed downwardly from the interlayer insulating layers 120 and other gate electrodes 130, and the regions may be referred to as pad regions 130P. The gate electrodes 130 may be connected to the first cell contact plugs 152 in the pad regions 130P. The gate electrodes 130 may have an increased thickness in the pad regions 130P.

The gate electrodes 130 may include a metallic material, such as tungsten (W). According to one or more example implementations, the gate electrodes 130 may include polycrystalline silicon or a metal silicide material. In some implementations, the gate electrodes 130 may further include a diffusion barrier, and may include, for example, tungsten nitride (WN), tantalum nitride (TaN), titanium nitride (TiN), or combinations thereof.

The interlayer insulating layers 120 may be disposed between the gate electrodes 130. The interlayer insulating layers 120 may also be spaced apart from each other in a direction, perpendicular to the lower surface of the plate layer 101 and may extend in the Y-direction, similar to the gate electrodes 130. The interlayer insulating layers 120 may include an insulating material such as silicon oxide or silicon nitride.

Each of the channel structures CH may be included in a single memory cell string and may be spaced apart from each other in rows and columns on the lower surface of the plate layer 101. The channel structures CH may be disposed to form a grid pattern on a plan view or may be disposed in a zigzag shape in one direction. The channel structures CH may have a pillar shape, and may have inclined side surfaces so that a width thereof becomes narrower as the channel structures CH move closer to the plate layer 101 depending on the aspect ratio.

Each of the channel structures CH may have a form in which the first and second channel structures CH1 and CH2 penetrating through the lower and upper stack structures of the gate electrodes 130 are connected, and may have a bent portion due to a difference or change in width in a connection region. However, according to one or more implementations, the number of channel structures stacked in the Z-direction may be variously changed.

Each of the channel structures CH may include a channel layer 140, a gate dielectric layer 145, a channel-filled insulating layer 147, and a channel pad 149, which are disposed in a channel hole. The channel layer 140 may be formed as an annular shape surrounding the channel-filled insulating layer 147 inside, but may also have a columnar shape such as a cylinder or a prism without the channel-filled insulating layer 147 according to one or more implementations. The channel layer 140 may include a semiconductor material such as polycrystalline silicon or single-crystal silicon. The channel layer 140 may be exposed through an upper end thereof and may be connected to the plate layer 101.

As illustrated in FIG. 9B, in an upper end of the channel structure CH, the upper end of the channel layer 140 may be exposed from the channel dielectric layer 145. The upper end of the channel layer 140 may include an upper surface and an upper region of a side surface connected to the upper surface. The upper end of the channel layer 140 may be in direct contact with the plate layer 101 and may be surrounded by the plate layer 101. By such an arrangement, the channel layer 140 may be physically and electrically connected to the plate layer 101.

The gate dielectric layer 145 may be disposed between the gate electrodes 130 and the channel layer 140. Although not specifically illustrated, the gate dielectric layer 145 may include a tunneling layer, a charge storage layer, and a blocking layer sequentially stacked from the channel layer 140. The tunneling layer may tunnel charges into the charge storage layer, and may include, for example, silicon oxide (SiO₂), silicon nitride (Si₃N₄), silicon oxynitride (SiON), or combinations thereof. The charge storage layer may be a charge trap layer or a floating gate conductive layer. The blocking layer may include silicon oxide (SiO₂), silicon nitride (Si₃N₄), silicon oxynitride (SiON), a high-κ dielectric material, or combinations thereof. In some implementations, at least a portion of the gate dielectric layer 145 may extend horizontally along the gate electrodes 130.

The channel pad 149 may be disposed only in a lower end of the second channel structure CH2. The channel pads 149 may include, for example, doped polycrystalline silicon.

The channel layer 140, the gate dielectric layer 145 and the channel-filled insulating layer 147 may be connected to each other between the first channel structure CH1 and the second channel structure CH2. A relatively thick interlayer insulating layer 120 may be further disposed between the first channel structure CH1 and the second channel structure CH2. However, the shape of the interlayer insulating layers 120 may be variously changed in example implementations.

The separation region MS may be disposed to extend in one direction, for example, the X-direction, through the gate electrodes 130. Although only one separation region MS is illustrated in FIG. 1, a plurality of separation regions MS may be disposed to extend in parallel with each other in the X-direction and spaced apart from each other in the Y-direction. The separation region MS may penetrate through entire gate electrodes 130 stacked on the plate layer 101 and may be connected to the plate layer 101.

The separation region MS may have a shape in which a width thereof decreases toward the plate layer 101 due to a high aspect ratio, but the present disclosure is not limited thereto. The separation region MS may include an insulating material, and may include, for example, silicon oxide, silicon nitride, or silicon oxynitride.

The first and second cell contact plugs 152 and 154 may extend in the Z-direction, and may have inclined side surfaces so that a width becomes narrower as the first and second cell contact plugs 152 and 154 move closer to the plate layer 101. Upper ends of the first and second cell contact plugs 152 and 154 may be disposed on a lower surface of the plate layer 101, for example, in the lower surface or inside the plate layer 101. The first and second cell contact plugs 152 and 154 may be included in a portion of the second interconnection structure in the second substrate structure S2.

The first cell contact plugs 152 may electrically connect the gate electrodes 130 to the first interconnection structure in the first substrate structure S1. The first cell contact plugs 152 may be physically and electrically connected to the gate electrodes 130 at respective pad regions 130P thereof, thus applying electrical signals to the gate electrodes 130. The first cell contact plugs 152 may penetrate through the pad regions 130P of the gate electrodes 130. The first cell contact plugs 152 may be disposed to extend into the plate layer 101 by penetrating through a region in which the gate electrodes 130 form a stepped structure. The first cell contact plugs 152 may be electrically separated from the plate layer 101 by the cover insulating layer 105. However, in some example implementations, the first cell contact plugs 152 may have a form that does not penetrate through the gate electrodes 130. In this case, the first cell contact plugs 152 may extend to be connected to lower surfaces or lower portions of each of the gate electrodes 130.

The first cell contact plugs 152 may have a horizontally extended shape in the pad regions 130P. The first cell contact plugs 152 may be separated from the gate electrodes 130 on the pad regions 130P by the contact insulating layers 125. The contact insulating layers 125 may surround a side surface of one first cell contact plug 152 and may be disposed to be separated from each other in the Z-direction. The contact insulating layers 125 may be disposed at substantially the same level as a level of the gate electrodes 130. The contact insulating layers 125 may include an insulating material, for example, silicon oxide, silicon nitride, or silicon oxynitride.

The second cell contact plugs 154 may be disposed in a region in which the gate electrodes 130 are not disposed, for example, in the outside of the gate electrodes 130. The second cell contact plug 154 may electrically connect the first and second circuit elements TR1 and TR2 of the first substrate structure S1 and the plate layer 101. The second cell contact plug 154 may extend into the plate layer 101 by penetrating through a portion of the cell region insulating layer 190.

The first and second cell contact plugs 152 and 154 may include a metallic material, and may include, for example, tungsten (W), aluminum (Al), copper (Cu), tungsten nitride (WN), tantalum nitride (TaN), titanium nitride (TiN), or combinations thereof.

The cover insulating layer 105 may be disposed between the first cell contact plugs 152 and the plate layer 101. The cover insulating layer 105 may cover upper ends of the first cell contact plugs 152. The cover insulating layer 105 may not extend over the channel structures CH and the second cell contact plugs 154. An upper surface of the cover insulating layer 105 may have a curve along the upper ends of the first cell contact plugs 152, but the shape of the upper surface of the cover insulating layer 105 is not limited thereto. The cover insulating layer 105 may include an insulating material, for example, at least one of silicon oxide, silicon nitride, or silicon carbide. In some example implementations, the cover insulating layer 105 may be disposed to have a plurality of layers spaced apart from each other between the first cell contact plugs 152. In some example implementations, the cover insulating layer 105 may be disposed to penetrate through the plate layer 101.

The cell upper contacts 170 and the cell interconnection lines 180 may be included in a portion of the second interconnection structure and may electrically connect the second substrate structure S2 to the first substrate structure S1.

The cell upper contacts 170 may include first to third cell upper contacts 172, 174 and 176, and the cell interconnection lines 180 may include first and second cell interconnection lines 182 and 184. The channel pads 149 and the first and second cell contact plugs 152 and 154 may be connected to the first cell upper contacts 172 from a lower end. The first cell upper contacts 172 may be connected to the second cell upper contacts 174 in the lower end, and the second cell upper contacts 174 may be connected to the first cell interconnection lines 182 in the lower end. The third cell upper contacts 176 may connect the first and second cell interconnection lines 182 and 184 vertically. The cell upper contacts 170 may have a cylindrical shape. In some implementations, the cell upper contacts 170 may have inclined side surfaces so that a width thereof deceases as the cell upper contacts 170 move closer the plate layer 101 and increases toward the first substrate structure S1, according to the aspect ratio.

The first cell interconnection lines 182 may include bit lines connected to the channel structures CH and interconnection lines arranged at the same height level as the bit lines. The second cell interconnection lines 184 may be interconnection lines disposed below the first cell interconnection lines 182. The cell interconnection lines 180 may have a line shape extending in at least one direction. In some implementations, the second cell interconnection lines 184 may have a thickness greater than a thickness of the first cell interconnection lines 182. The cell interconnection lines 180 may have inclined side surfaces so that a width thereof decreases toward the plate layer 101.

The cell upper contacts 170 and the cell interconnection lines 180 may include, for example, tungsten (W), aluminum (Al), copper (Cu), tungsten nitride (WN), tantalum nitride (TaN), titanium nitride (TiN), or combinations thereof.

The second bonding vias 195 of the second bonding structure may be disposed below the second cell interconnection lines 184 and may be connected to the second cell interconnection lines 184, and the second bonding pads 198 of the second bonding structure may be connected to the second bonding vias 195. The second bonding pads 198 may have lower surfaces exposed to a lower surface of the second substrate structure S2. The second bonding pads 198 may be bonded and connected by the first bonding pads 298 of the first substrate structure S1, and the second bonding insulating layer 199 may be bonded and connected by the first bonding insulating layer 299 of the first substrate structure S1. The second bonding vias 195 and the second bonding pads 198 may include a conductive material, for example, copper (Cu). The second bonding insulating layer 199 may include, for example, at least one of SiO₂, SiN, SiCN, SiOC, SiON, or SiOCN.

The first and second substrate structures S1 and S2 may be bonded to each other by bonding of the first bonding pads 298 and the second bonding pads 198 and bonding of the first bonding insulating layer 299 and the second bonding insulating layer 199. The bonding of the first bonding pads 298 and the second bonding pads 198 may be, for example, copper (Cu)-copper (Cu) bonding, and the bonding of the first bonding insulating layer 299 and the second bonding insulating layer 199 may be, for example, dielectric-dielectric bonding, such as SiCN—SiCN bonding. The first and second substrate structures S1 and S2 may be bonded to each other by hybrid bonding including copper (Cu)-copper (Cu) bonding and dielectric-dielectric bonding.

The cell region insulating layer 190 may be disposed to cover the lower surface of the plate layer 101 and the gate electrodes 130 on the lower surface of the plate layer 101. The passivation layer 106 may be disposed on the upper surface of the plate layer 101 and may have an opening exposing an input/output pad region (IOP). The passivation layer 106 may function as a layer protecting the semiconductor device 100.

The cell region insulating layer 190 and the passivation layer 106 may include at least one of an insulating material, for example, silicon oxide, silicon nitride, or silicon carbide, and may be formed of a plurality of insulating layers according to one or more implementations.

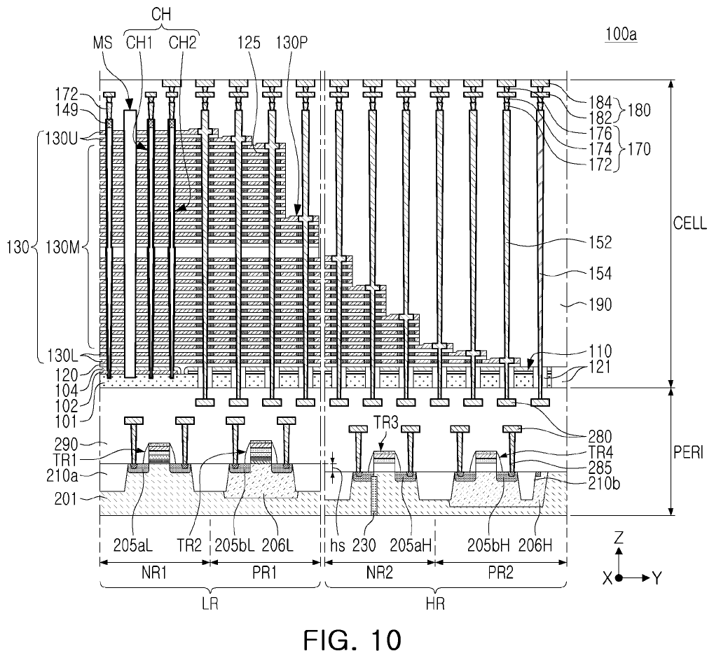

FIG. 10 is a cross-sectional view of a semiconductor device according to one or more implementations.

Referring to FIG. 10, a semiconductor device 100a may include a peripheral circuit region PERI including the substrate 1 and a memory cell region CELL including the plate layer 101. The memory cell region CELL may be disposed on the peripheral circuit region PERI. In some implementations, on the contrary, the memory cell region CELL may be disposed below the peripheral circuit region PERI.

The description of the first semiconductor structure S1 described above with reference to FIGS. 8 to 9A may be applied to the peripheral circuit region PERI. However, unlike the first semiconductor structure S1, the peripheral circuit region PERI may not include the first bonding vias 295, the first bonding pads 298 and the first bonding insulating layers 299 included in the bonding structure.

For the memory cell region CELL, unless otherwise described, the description of the second semiconductor structure S2 described above with reference to FIGS. 6 to 8 may be applied. However, unlike the second semiconductor structure S2, the memory cell region CELL may not include the second bonding vias 195, the second bonding pads 198, and the second bonding insulating layer 199, which are included in the bonding structure, and may not include the passivation layer 106. The memory cell region CELL may further include first and second horizontal conductive layers 102 and 104 on the plate layer 101, a horizontal insulating structure 110, and a substrate penetration insulating layer 121.

The first and second horizontal conductive layers 102 and 104 may be sequentially stacked and disposed on the upper surface of the plate layer 101. The first horizontal conductive layer 102 may function as a portion of a common source line of a semiconductor device 100f, and may function, for example, as a common source line together with the plate layer 101. The first horizontal conductive layer 102 may be directly connected to the channel layer 140 at the periphery of each of the channel structures CH. The first and second horizontal conductive layers 102 and 104 may include a semiconductor material, and may include, for example, polycrystalline silicon.

The horizontal insulating structure 110 may be disposed on the plate layer 101 in parallel with the first horizontal conductive layer 102. The horizontal insulating structure 110 may include three horizontal insulating layers sequentially stacked on the plate layer 101. The horizontal insulating structure 110 may be layers remaining after a portion of the semiconductor device 100a is replaced with the first horizontal conductive layer 102 during the manufacturing process. The horizontal insulating structure 110 may include silicon oxide, silicon nitride, silicon carbide, or silicon oxynitride.

The substrate penetration insulating layer 121 may be disposed to penetrate through the plate layer 101, the horizontal insulating structure 110, and the second horizontal conductive layer 104. An upper surface of the substrate penetration insulating layer 121 may be coplanar with an upper surface of the second horizontal conductive layer 104, but the present disclosure is not limited thereto. The substrate penetration insulating layer 121 may include an insulating material, for example, silicon oxide, silicon nitride, silicon carbide, or silicon oxynitride.

In one or more implementations, the first and second cell contact plugs 152 and 154 may penetrate through the gate electrodes 130 and may then penetrate through the substrate penetration insulating layer 121 to be connected to the circuit interconnection lines 280 of the peripheral circuit region PERI.

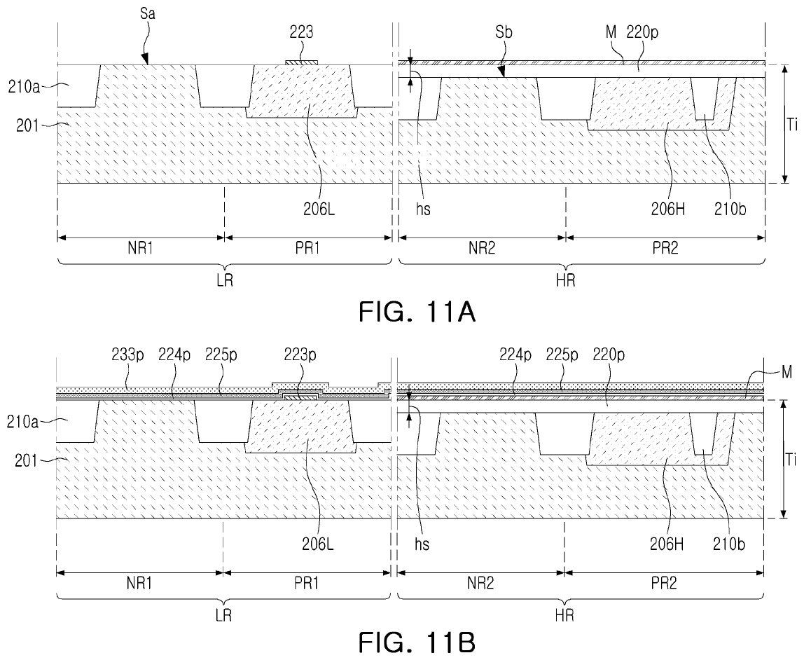

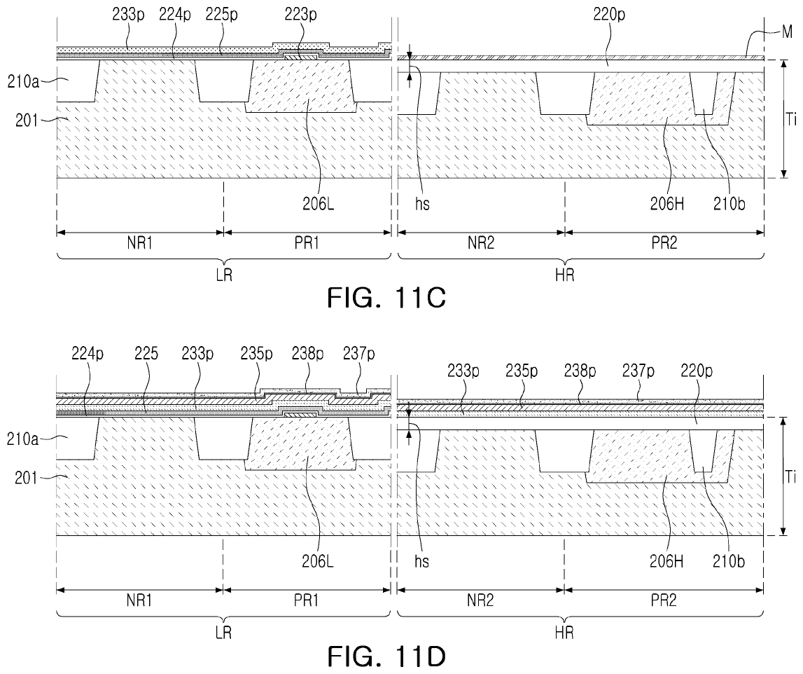

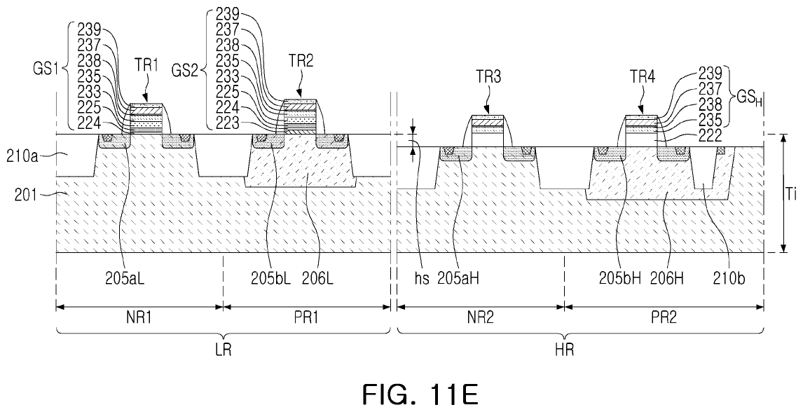

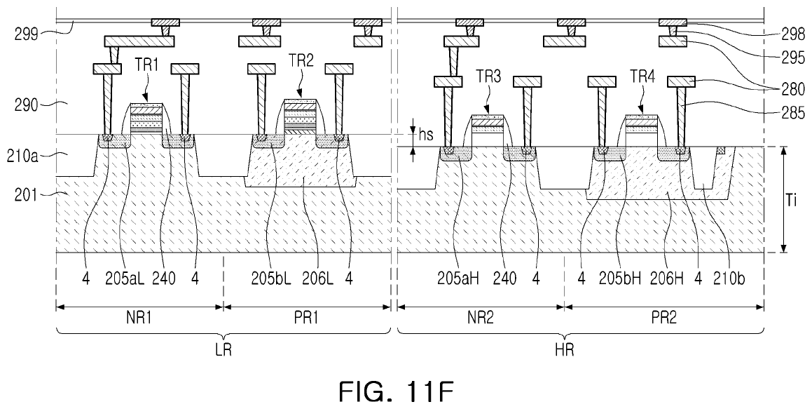

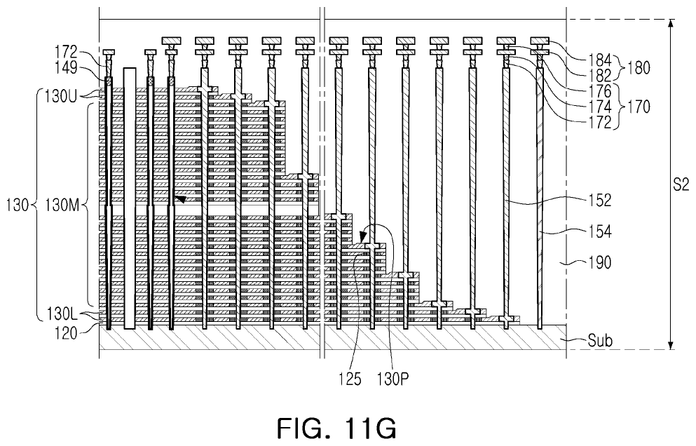

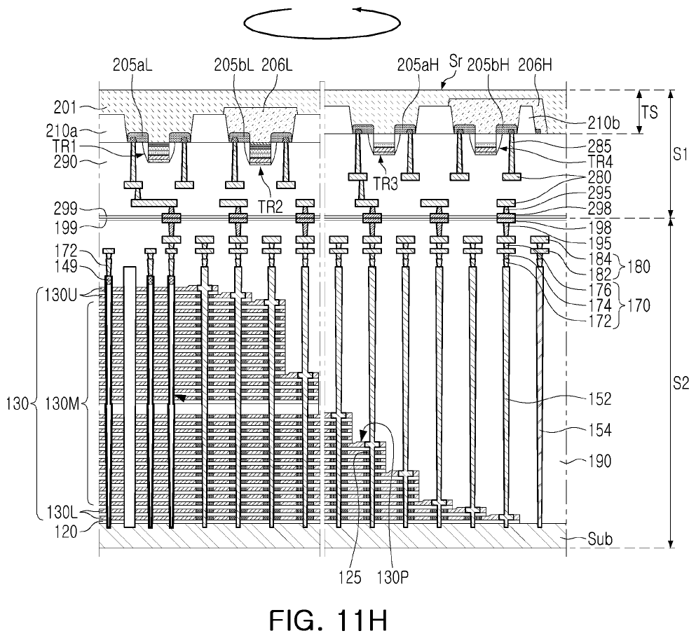

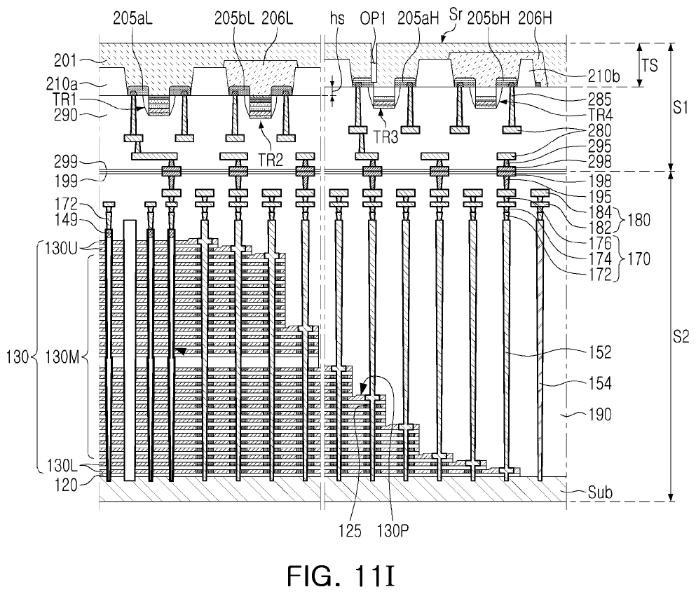

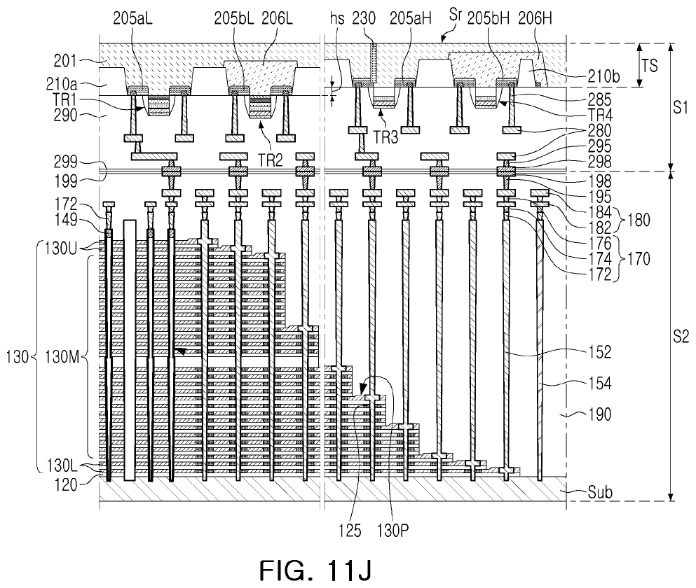

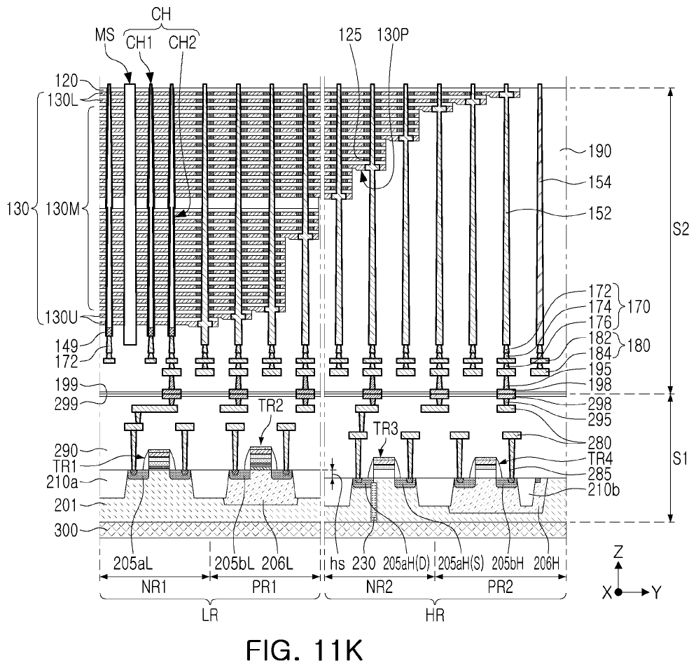

FIGS. 11A to 11K are schematic cross-sectional views illustrating a method of manufacturing a semiconductor device 100 according to one or more implementations. FIGS. 10A to 10K illustrate a region corresponding to FIG. 8.

Referring to FIG. 11A, a substrate 201 may be prepared.

The substrate 201 may have an initial thickness Ti from the upper surface Sa to the lower surface Sr, may be a semiconductor substrate, and may be, for example, a silicon wafer. On the upper surface in which the circuit elements of the substrate 201 are disposed, a region forming the high-voltage element region HR and the low-voltage element region LR may be divided, and may be etched so that an upper surface of the high-voltage element region HR has a substrate step portion hs from an upper surface of the low-voltage element region LR. Accordingly, the substrate 201 may have a first upper surface Sa in the low-voltage element region LR, and may have a second upper surface Sb in the high-voltage element region HR, which is disposed at a level reduced by the substrate step portion hs. The initial thickness Ti, which is a length in the Z-direction from the first upper surface Sa of the substrate 201 to the lower surface Sr, may be greater than a substrate thickness Ts of FIG. 8.

Impurities may be doped into the second element region PR1 and the fourth element region PR2 in which the PMOS transistors in the high-voltage element region HR and the low-voltage element region LR are disposed to form first and second well regions 206L and 206H, and element isolating regions 210a and 210b may be formed, respectively. The element isolating regions 210a and 210b may be formed by forming a shallow trench and stacking oxides, but the present disclosure is not limited thereto.

A preliminary gate dielectric layer 220p may be formed on the substrate 201 of the high-voltage element region HR with the same thickness T7 as the substrate step portion hs. The preliminary gate dielectric layer 220p may be formed to have a large thickness using a material having a low dielectric constant, such as silicon oxide or silicon oxynitride.

An etching mask layer M may be further formed on the preliminary gate dielectric layer 220p. The etching mask layer M may be formed of polysilicon with a significantly thin thickness, and may be selectively formed only in the high voltage element region HR.

In the low voltage element region LR, a channel structure 223 may be further formed in an area in which the second gate structure GS2 is formed on the substrate 201 of the second element region PR1. The channel structure 223 may include a semiconductor material having a smaller band gap than the substrate 201 material, and may include silicon-germanium.

Referring to FIG. 11B, a preliminary interface insulating layer 224p, a preliminary gate dielectric layer 225, and a preliminary first conductive layer 233p may be sequentially formed throughout the low voltage element region LR and the high voltage element region HR.

The preliminary interface insulating layer 224p may be formed by stacking materials included in the first and second interface insulating layers 224 on the first and second upper surfaces Sa and Sb of the substrate 201 as a whole, and may be formed by depositing silicon oxide. The preliminary gate dielectric layer 225 may include a high-κ material, may be deposited to have a thickness greater than a thickness of the preliminary interface insulating layer 224p, and may be formed by depositing hafnium oxide (HfO) on the preliminary interface insulating layer 224p, but the present disclosure is not limited thereto.

The preliminary first conductive layer 233p may include a metal nitride, and may be formed by depositing titanium nitride.

As illustrated in FIG. 11C, the stacked material layers of the high-voltage element region HR may be etched to expose the etching mask layer M.

That is, the material layers stacked only in the low-voltage element region LR may remain, and other layers from the preliminary interface insulating layer 224p stacked on the etching mask layer M to the preliminary first conductive layer 233p in the high-voltage element region HR may be completely removed.

Referring to FIG. 11D, a preliminary second conductive layer 235p, a preliminary ohmic contact layer 238p and a preliminary third conductive layer 237p may be sequentially stacked throughout the low-voltage element region LR and the high-voltage element region HR as a whole.

The preliminary second conductive layer 235p may include polysilicon, and may be formed without a boundary with the etching mask layer M by including the same material as the etching mask layer M.

The preliminary ohmic contact layer 238p may be formed to have a significantly thin thickness using a material such as tantalum nitride or titanium nitride. The preliminary third conductive layer 237p may be formed on the preliminary ohmic contact layer 238p. The preliminary third conductive layer 237p may include a metal material such as tungsten or aluminum.

Referring to FIG. 11E, a mask layer 239 may be formed in a region indicating the gate structures GS1, GS2 and GS_{H} of the first to fourth circuit elements TR1 to TR4, and then etched to form the gate structures GS1, GS2 and GS_{H}, respectively.

The mask layer 239 may be silicon nitride, or silicon oxynitride, and may be patterned as a mask to form the gate structures GS1, GS2 and GS_{H} defining each circuit element TR1 to TR4.

Heights of the gate structures GS1, GS2 and GS_{H}, may be the highest for the second circuit element TR2, and may be the lowest for the third and fourth circuit elements TR3 and TR4.

Then, by performing an ion implantation process using the gate structures GS1, GS2 and GS_{H} as a mask, source/drain regions 205aL, 205bL, 205aH and 205bH may be formed in the substrate 201 on both sides of the respective gate structure GS1, GS2 and GS_{H}. The source/drain regions 205aL, 205bL, 205aH and 205bH may include a source region S and a drain region D on both sides of the gate structure GS1, GS2 and GS_{H}, respectively, and a low concentration doping region 2 and a high concentration doping region 4 may be formed on each of the source region S and the drain region D.

Then, gate spacers 240 may be formed on both sidewalls of the gate structure GS1, GS2 and GS_{H} of each circuit element TR1 to TR4, so that the first to fourth gate structures GS1, GS2 and GS_{H} may be formed. Accordingly, the first to fourth circuit elements TR1 to TR4 may be completed.

Then, referring to FIG. 11f, circuit structures may be formed on the first to fourth circuit elements TR1 to TR4. The contact plugs 285 may be formed by partially forming a peripheral region insulating layer 290, then partially etching and removing the peripheral region insulating layer, and then filling the removed portion with a conductive material. The circuit interconnection lines 280 may be formed, for example, by depositing a conductive material and then patterning the conductive material.

Then, a first bonding insulating layer 299 may be formed on the circuit interconnection lines 280. The first bonding vias 295 and the first bonding pads 298 of the first bonding structure may be formed after partially removing the first bonding insulating layer 299 and the peripheral region insulating layer 290.

Through the present operation, the first substrate structure S1 may be prepared.

Next, referring to FIG. 11G, a second substrate structure S2 may be manufactured.

The second substrate structure S2 may alternately stack sacrificial insulating layers and interlayer insulating layers 120 on a base substrate Sub.

The base substrate Sub is a layer removed through a subsequent process, and may be a semiconductor substrate such as undoped silicon (Si). The sacrificial insulating layers may be layers replaced with the gate electrodes 130 (see FIG. 8) through a subsequent process. The sacrificial insulating layers may be formed of a material that may be etched with etch selectivity with respect to the interlayer insulating layers 120. For example, the interlayer insulating layer 120 may be formed of at least one of silicon oxide or silicon nitride, and the sacrificial insulating layers may be formed of a material different from a material of the interlayer insulating layer 120 selected from silicon, silicon oxide, silicon carbide, and silicon nitride. In some implementations, a thickness of the interlayer insulating layers 120 and the number of films included in interlayer insulating layers 120 may be variously changed from those illustrated.

Then, in regions including ends of the sacrificial insulating layers, a photolithography process and an etching process may be repeated to form a staircase shape. The sacrificial insulating layers may be formed to have a relatively thick thickness in the ends, and a process therefor may be further performed. A portion of the cell region insulating layer 190 covering a lower stacked structure of the sacrificial insulating layers and the interlayer insulating layers 120 may be formed.

Vertical sacrificial layers may be formed by corresponding to each channel structure, and the vertical sacrificial layers may include, for example, polycrystalline silicon.

Channel structures CH penetrating through the stacked structure of the sacrificial insulating layers and the interlayer insulating layers 120 may be formed.

First, the vertical sacrificial layers may be removed to form channel holes. Next, a gate dielectric layer 145, a channel layer 140, a channel-filled insulating layer 147, and a channel pad 149 may be sequentially formed in each of the channel holes, thereby forming the channel structures CH including the first and second channel structures CH1 and CH2. The channel layer 140 may be formed on the gate dielectric layer 145 in the channel structures CH. The channel-filled insulating layer 147 may be formed to fill the channel structures CH and may be an insulating material. However, according to one or more implementations, a space between the channel layers 140 may be filled with a conductive material other than the channel-filled insulating layer 147. The channel pads 149 may be formed of a conductive material, and may be formed of, for example, polycrystalline silicon.

Next, in a region corresponding to the separation region MS, an opening extending to the plate layer 101 penetrating through the sacrificial insulating layers and the interlayer insulating layers 120 may be formed, and the sacrificial insulating layers may be removed by supplying an etchant through the opening. The sacrificial insulating layers may be selectively removed with respect to the interlayer insulating layers 120, etc., for example, using wet etching.

The gate electrodes 130 may be formed by depositing a conductive material in regions from which the sacrificial insulating layers are removed. The conductive material may include a metal, polycrystalline silicon, or a metal silicide material. After forming the gate electrodes 130, an insulating material may be deposited in the opening to form the separation region MS.

Then, the first cell contact plugs 152 may be formed by depositing a conductive material in the contact holes. When the contact sacrificial layers previously formed in the region in which the contact holes are formed are removed, a portion of the insulating material may also be removed. In this case, the insulating material may be completely removed from the pad regions 130P, and the insulating material may remain therebelow, thus forming contact insulating layers 125. The first cell contact plugs 152 may be formed to have regions expanded horizontally from the pad regions 130P, and may thus be physically and electrically connected to the gate electrodes 130. The second cell contact plugs 154 may be formed by forming separate contact holes extending into the base substrate Sub by penetrating through the cell region insulating layer 190 on the outside of the gate electrodes 130, and depositing a conductive material into the contact holes. A deposition process of the conductive material may be performed simultaneously with a deposition process for the first cell contact plugs 152, but the present disclosure is not limited thereto.

A second interconnection structure and a second bonding structure may be formed on the gate electrodes 130. In the second interconnection structure, the cell upper contacts 170 may be formed by etching the cell region insulating layer 190 on the channel pads 149 and the first and second cell contact plugs 152 and 154 and depositing a conductive material thereon. The cell interconnection lines 180 may be formed through a deposition and patterning process of a conductive material, or by partially forming the cell region insulating layer 190, then patterning the cell region insulating layer 190, and depositing a conductive material thereon.

In the second bonding structure, the second bonding insulating layer 199 may be formed on the cell region insulating layer 190. Then, the second bonding insulating layer 199 and the cell region insulating layer 190 may be partially removed, and a conductive material may be deposited to form second bonding vias 195, and then second bonding pads 198 may be formed on the second bonding vias 195. In some example implementations, the second bonding via 195 and the second bonding pad 198 disposed vertically may be formed integrally with each other. Upper surfaces of the second bonding pads 198 may be exposed from the cell region insulating layer 190.

Referring to FIG. 11H, the first substrate structure S1 and the second substrate structure S2 may be connected to each other by bonding the first bonding pads 298 and the second bonding pads 198 in annealing and/or pressurizing processes. At the same time, the first bonding insulating layer 299 and the second bonding insulating layer 199 may also be bonded. At this time, the first substrate structure S1 may be flipped over on the second substrate structure S2 so that the first bonding pads 298 face downwardly, and then the bonding may be performed. The first substrate structure S1 and the second substrate structure S2 may be directly bonded to each other without the intervention of an adhesive such as a separate adhesive layer.

On the bonding structure of the first and second substrate structures S1 and S2, a portion of the substrate 201 may be removed to reduce a thickness of the substrate 201 from the initial thickness Ti to the substrate thickness Ts. In this case, a portion of the substrate 201 may be removed through a polishing process such as a grinding process.

Referring to FIG. 11I, openings OP1 may be formed in a region in which the separation trench structures 230 are disposed on a ground lower surface Sr of the exposed substrate 201.

The openings OP1 may be formed by performing laser etching or plasma etching, and may be formed as trenches extending in the Z-direction from the lower surface Sr of the substrate 201 to a level corresponding to the second distance d2 from the upper surface Sb of the substrate 201 in boundaries between the third drain region 205aH(D) and the channel region ACT_{N} of the third circuit elements TR3. The shape of the openings OP1 may have a bar type shape on the X-Y plane, but may have a wall shape by extending in the Z-direction.

In this case, the openings OP1 may be formed by etching the lower surface of the element isolating layer 210b at once with a stopper up to the lower surface of the element isolating layer 210b, and then sequentially etching the element isolating layer 210b by a target depth, but the present disclosure is not limited thereto.

In each NMOS transistor of a polymer element region HR, openings OP1 may be formed in boundaries between the third drain region 205aH(D) and the channel region ACT_{N}, thus preventing carriers from being transferred from the third drain region 205aH(D) through the substrate 201 below the channel region ACT_{N}.

Referring to FIG. 11J, an insulating material may be filled in the openings OP1 to form the separation trench structures 230.

The insulating material may include silicon oxide, silicon nitride, and silicon oxynitride, and may be formed by depositing high-κ materials and then planarizing the high-k materials so that lower surfaces of the separation trench structures 230 and the lower surface Sr of the substrate 201 are coplanar with each other.

Referring to FIG. 11K, in a state in which the first substrate structure S1 and the second substrate structure S2 bonded to each other are flipped over and disposed on a carrier substrate 300, and the base substrate Sub of the second substrate structure S2 is exposed to an upper surface thereof, the base substrate Sub may be removed.

For example, a portion of the base substrate Sub may be removed from the upper surface in a polishing process such as a grinding process, and the remaining portion thereof may be removed in an etching process such as wet etching. By removing the base substrate Sub of the second substrate structure S2, a total thickness of the semiconductor device may be minimized. By removing the base substrate Sub, upper ends of the channel structures CH and the first and second cell contact plugs 152 and 154 may be exposed. The channel dielectric layers 145 (see FIG. 9B) may be partially removed from upper portions of the exposed channel structures CH.

Then, as illustrated in FIG. 8, the plate layer 101 may be formed on the upper portions of the channel structures CH, and an insulating material may be deposited on the upper portions of the exposed first cell contact plugs 152 to form a cover insulating layer 105.

The plate layer 101 may be formed by depositing a semiconductor material. The plate layer 101 may be formed by, for example, depositing amorphous silicon (Si) and then crystallizing amorphous silicon (Si). The passivation layer 106 may be formed on the plate layer 101.

Thereby, the semiconductor device 100 of FIG. 8 may be manufactured.

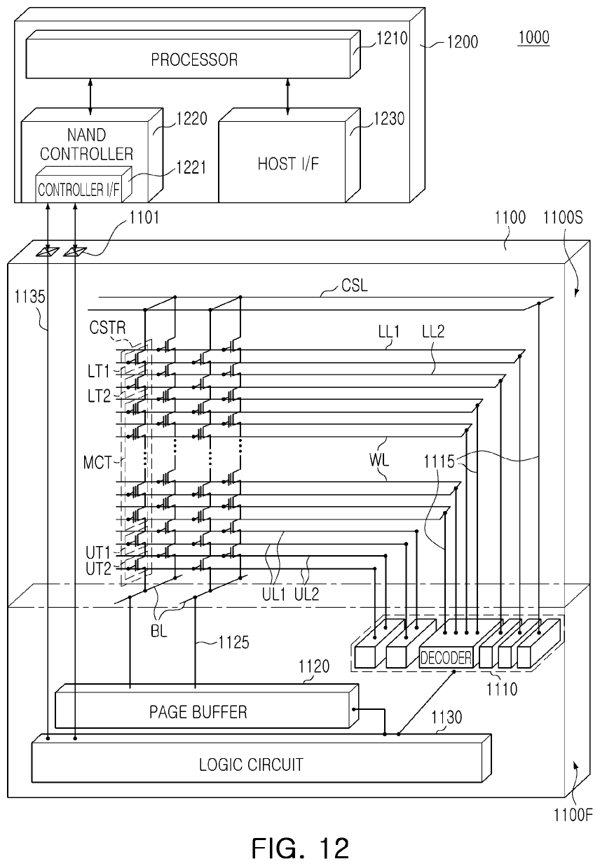

FIG. 12 is a view schematically illustrating a data storage system including a semiconductor device according to one or more implementations.

Referring to FIG. 12, a data storage system 1000 may include a semiconductor device 1100 and a controller 1200 electrically connected to the semiconductor device 1100. The data storage system 1000 may be a storage device including one or more semiconductor devices 1100 or an electronic device including the storage device. For example, the data storage system 1000 may be a solid state drive device (SSD), a Universal Serial Bus (USB), a computing system, a medical device, or a communication device, including one or more semiconductor devices 1100.

The semiconductor device 1100 may be a nonvolatile memory device, and may be, for example, a NAND flash memory device described above with reference to FIGS. 8 to 10. The semiconductor device 1100 may include a first structure 1100F and a second structure 1100S on the first structure 1100F. In some implementations, the first structure 1100F may be disposed next to the second structure 1100S. The first structure 1100F may be a peripheral circuit structure including a decoder circuit 1110, a page buffer 1120, and a logic circuit 1130. The second structure 1100S may be a memory cell structure including a bit line BL, a common source line CSL, word lines WL, first and second gate upper lines UL1 and UL2, first and second gate lower lines LL1 and LL2, and a memory cell string CSTR between the bit line BL and the common source line CSL.

In the second structure 1100S, each memory cell string CSTR may include lower transistors LT1 and LT2 adjacent to a common source line CSL, upper transistors UT1 and UT2 adjacent to a bit line BL, and a plurality of memory cell transistors MCT disposed between the lower transistors LT1 and LT2 and the upper transistors UT1 and UT2. The number of lower transistors LT1 and LT2 and the number of upper transistors UT1 and UT2 may be variously according to one or more implementations.

In some implementations, the upper transistors UT1 and UT2 may include string select transistors, and the lower transistors LT1 and LT2 may include ground select transistors. The gate lower lines LL1 and LL2 may be gate electrodes of the lower transistors LT1 and LT2, respectively. The word lines WL may be gate electrodes of the memory cell transistors MCT, and the gate upper lines UL1 and UL2 may be gate electrodes of the upper transistors UT1 and UT2, respectively.

In some implementations, the lower transistors LT1 and LT2 may include a serially connected lower erase control transistor LT1 and a ground select transistor LT2. The upper transistors UT1 and UT2 may include a serially connected string select transistor UT1 and an upper erase control transistor UT2. At least one of the lower erase control transistor LT1 or the upper erase control transistor UT2 may be used for an erase operation that erases data stored in the memory cell transistors MCT by utilizing a GIDL phenomenon.

The common source line CSL, the first and second gate lower lines LL1 and LL2, the word lines WL, and the first and second gate upper lines UL1 and UL2 may be electrically connected to the decoder circuit 1110 through first interconnection lines 1115 extending from the first structure 1100F to the second structure 1100S. The bit lines BL may be electrically connected to the page buffer 1120 through second interconnection lines 1125 extending from the first structure 1100F to the second structure 1100S.

In the first structure 1100F, the decoder circuit 1110 and the page buffer 1120 may perform a control operation for at least one selected memory cell transistor among the plurality of memory cell transistors MCT. The decoder circuit 1110 and the page buffer 1120 may be controlled by the logic circuit 1130. The semiconductor device 1100 may communicate with the controller 1200 through an input/output pad 1101 electrically connected to the logic circuit 1130. The input/output pad 1101 may be electrically connected to the logic circuit 1130 through an input/output connection interconnection 1135 that extends from the first structure 1100F to the second structure 1100S.

The controller 1200 may include a processor 1210, a NAND controller 1220, and a host interface 1230. According to example implementations, the data storage system 1000 may include a plurality of semiconductor devices 1100, and in this case, the controller 1200 may control the plurality of semiconductor devices 1100.

The processor 1210 may control an overall operation of the data storage system 1000 including the controller 1200. The processor 1210 may operate according to a predetermined firmware, and may control the NAND controller 1220 to access the semiconductor device 1100. The NAND controller 1220 may include a NAND interface 1221 processing communication with the semiconductor device 1100. Through the NAND interface 1221, a control command for controlling the semiconductor device 1100, data to be recorded in the memory cell transistors MCT of the semiconductor device 1100, data to be read from the memory cell transistors MCT of the semiconductor device 1100, or the like, may be transmitted. The host interface 1230 may provide a communication function between the data storage system 1000 and an external host. When receiving a control command from the external host through the host interface 1230, the processor 1210 can control the semiconductor device 1100 in response to the control command.

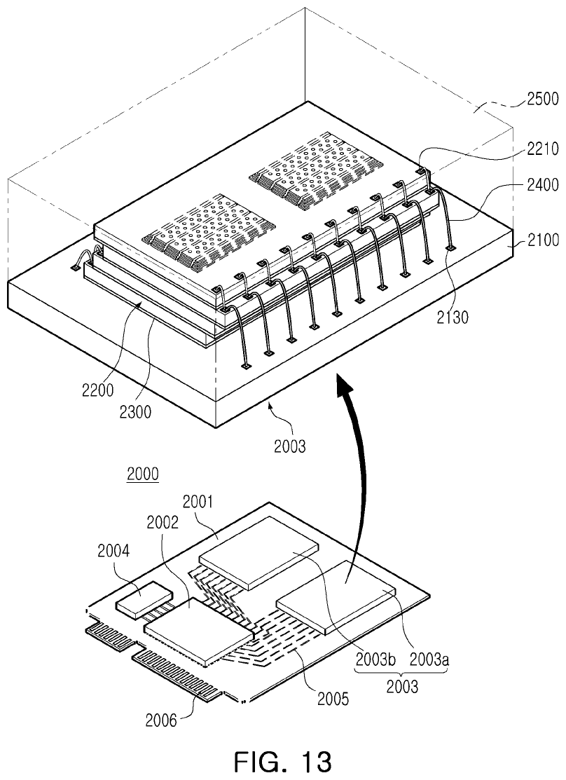

FIG. 13 is a perspective view schematically illustrating a data storage system including a semiconductor device according to one or more implementations.

Referring to FIG. 13, a data storage system 2000 according to one or more implementations of the present disclosure may include a main board 2001, a controller 2002 mounted on the main board 2001, one or more semiconductor packages 2003, and a DRAM 2004. The semiconductor package 2003 and the DRAM 2004 may be connected to each other with the controller 2002 by interconnection patterns 2005 formed on the main board 2001.

The main board 2001 may include a connector 2006 including a plurality of pins coupled to the external host. The number and arrangement of the plurality of pins in the connector 2006 may vary depending on the communication interface between the data storage system 2000 and the external host. In some implementations, the data storage system 2000 may communicate with the external host according to any one of interfaces such as Universal Serial Bus (USB), Peripheral Component Interconnect Express (PCI-Express), Serial Advanced Technology Attachment (SATA), and M-Phy for Universal Flash Storage (UFS). In some implementations, the data storage system 2000 may operate by power supplied from the external host through the connector 2006. The data storage system 2000 may further include a Power Management Integrated Circuit (PMIC) that distributes power supplied from the external host to the controller 2002 and the semiconductor package 2003.

The controller 2002 may record data to the semiconductor package 2003 or read data in or from the semiconductor package 2003, and may improve the operating speed of the data storage system 2000.

The DRAM 2004 may be a buffer memory for alleviating a speed difference between the semiconductor package 2003, which is a data storage space, and the external host. The DRAM 2004 included in the data storage system 2000 may also operate as a type of cache memory, and may provide a space for temporarily storing data in a control operation for the semiconductor package 2003. When the data storage system 2000 includes the DRAM 2004, the controller 2002 may further include a DRAM controller for controlling the DRAM 2004 in addition to the NAND controller for controlling the semiconductor package 2003.

The semiconductor package 2003 may include first and second semiconductor packages 2003a and 2003b spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, semiconductor chips 2200 on the package substrate 2100, adhesive layers 2300 disposed on lower surfaces of each of the semiconductor chips 2200, a connection structure 2400 electrically connecting the semiconductor chips 2200 and the package substrate 2100, and a molding layer 2500 covering the semiconductor chips 2200 and the connection structure 2400 on the package substrate 2100.

The package substrate 2100 may be a printed circuit board including package upper pads 2130. Each semiconductor chip 2200 may include an input/output pad 2210. The input/output pad 2210 may correspond to the input/output pad 1101 of FIG. 12. Each of the semiconductor chips 2200 may include gate stack structures 3210 and channel structures 3220. Each of the semiconductor chips 2200 may include the semiconductor device described above with reference to FIGS. 8 to 10.

In some implementations, the connection structure 2400 may be a bonding wire that electrically connects the input/output pad 2210 and the package upper pads 2130. Accordingly, in each of the first and second semiconductor packages 2003a and 2003b, the semiconductor chips 2200 may be electrically connected to each other in a bonding wire manner, and may be electrically connected to the package upper pads 2130 of the package substrate 2100. According to example implementations, in each of the first and second semiconductor packages 2003a and 2003b, the semiconductor chips 2200 may be electrically connected to each other by a connecting structure including a through-silicon via (TSV), instead of a connecting structure 2400 in a bonding wire manner.

In some implementations, the controller 2002 and the semiconductor chips 2200 may be included in one package. In one or more implementations, the controller 2002 and the semiconductor chips 2200 may be mounted on a separate interposer substrate different from the main substrate 2001, and the controller 2002 and the semiconductor chips 2200 may be connected to each other by interconnection lines formed on the interposer substrate.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

1. A semiconductor device comprising:
a substrate including an upper surface and a lower surface;
a gate structure on the upper surface of the substrate, the gate structure having a first length in a first direction parallel to the upper surface;
a drain region disposed in the substrate and extending from the upper surface of the substrate on a first side of the gate structure in the first direction;
a source region disposed in the substrate and extending from the upper surface of the substrate on a second side of the gate structure opposite to the first side of the gate structure in the first direction;
a channel region disposed in the substrate and extending from the upper surface of the substrate, below the gate structure, and between the drain region and the source region; and
a first separation trench structure extending from the lower surface of the substrate in a second direction perpendicular to the first direction, disposed in a boundary region between the channel region and the drain region, and spaced apart from the upper surface of the substrate.

2. The semiconductor device of claim 1,
wherein the drain region has a first width in a third direction parallel to the upper surface of the substrate and perpendicular to the first direction, and
wherein the first separation trench structure has a length in the third direction equal to or greater than the first width of the drain region in the third direction.

3. The semiconductor device of claim 1,
wherein a separation distance in the second direction between the first separation trench structure and the upper surface of the substrate is equal to or greater than a thickness of an inversion layer in the channel region.

4. The semiconductor device of claim 1,
wherein the first separation trench structure has an upper surface, and the upper surface has a second length in the first direction,
wherein the second length of the upper surface of the first separation trench structure is less than the first length of the gate structure.

5. The semiconductor device of claim 4,
wherein the upper surface of the first separation trench structure includes:
a first portion in contact with the drain region; and
a second portion extending from the first portion in the first direction and in contact with the channel region.

6. The semiconductor device of claim 5,
wherein a length of the second portion of the upper surface in the first direction is equal to or greater than a length of the first portion of the upper surface in the first direction.

7. The semiconductor device of claim 5,
wherein the drain region has a corner defined by at least a lower surface of the drain region and a side surface of the drain region, and the corner has a concave surface in contact with the first portion of the first separation trench structure.

8. The semiconductor device of claim 4,
wherein the upper surface of the first separation trench structure is disposed at a level between the upper surface of the substrate and a lower surface of the drain region.

9. The semiconductor device of claim 1,
wherein a lower surface of the first separation trench structure is coplanar with the lower surface of the substrate.

10. The semiconductor device of claim 1,
wherein a width of a lower surface of the first separation trench structure is greater than a width of an upper surface of the first separation trench structure.

11. The semiconductor device of claim 1,
wherein the first separation trench structure includes a first side surface and a second side surface opposing each other in the first direction and between an upper surface of the first separation trench structure and a lower surface of the first separation trench structure,
wherein the first side surface is in contact with the drain region in an upper portion of the first separation trench structure, and the second side surface is in contact with the substrate in the upper portion of the first separation trench structure.

12. The semiconductor device of claim 11,
wherein the first separation trench structure is in contact with a side surface of the drain region in the upper portion of the first side surface.

13. The semiconductor device of claim 1, further comprising:
a second separation trench structure extending from the lower surface of the substrate in the second direction and spaced apart from the upper surface of the substrate, the second separation trench structure being disposed in a boundary region between the channel region and the source region.

14. The semiconductor device of claim 13,
wherein a separation distance between the first separation trench structure and the second separation trench structure along the first direction is less than the first length of the gate structure.

15. The semiconductor device of claim 1,
wherein the semiconductor device includes an NMOS transistor.

16. The semiconductor device of claim 1,
wherein the drain region is configured to receive a drain voltage of 10 V to 30 V.

17. A semiconductor device, comprising:
a cell structure including gate electrodes, channel structures extending through the gate electrodes, and contact plugs connected to the gate electrodes; and
a peripheral circuit structure including:
a substrate electrically connected to the cell structure, the substrate having an upper surface and a lower surface;
a first element region and a second element region in the substrate;
N-type first circuit elements and P-type second circuit elements in the first element region; and
N-type third circuit elements and P-type fourth circuit elements in the second element region,
wherein at least one of the N-type third circuit elements comprises:
a gate structure on the upper surface of the substrate, the gate structure including a gate dielectric layer having a thickness greater than a thickness of gate dielectric layers of the N-type first and P-type second circuit elements, and a gate conductive layer on the gate dielectric layer;
a drain region disposed in the substrate and extending from the upper surface of the substrate on a first side of the gate structure in a first direction parallel to the upper surface of the substrate;
a source region disposed in the substrate and extending from the upper surface of the substrate on a second side of the gate structure opposite to the first side of the gate structure in the first direction;
a channel region disposed in the substrate and extending from the upper surface of the substrate, below the gate structure, and between the drain region and the source region; and
a separation trench structure extending from the lower surface of the substrate in a second direction perpendicular to the first direction, and spaced apart from the upper surface of the substrate, the separation trench structure disposed in a boundary region between the channel region and the drain region.

18. The semiconductor device of claim 17,
wherein a lower surface of the separation trench structure is coplanar with the lower surface of the substrate, and an upper surface of the separation trench structure is disposed at a level lower than a level of the upper surface of the substrate.

19. The semiconductor device of claim 17,
wherein the drain region has a first length in a third direction parallel to the upper surface of the substrate, and a length of the separation trench structure in the third direction is equal to or greater than the first length of the drain region.

20. A data storage system, comprising:
a semiconductor storage device including:
a substrate;
a first substrate structure including first to fourth circuit elements on the substrate; and
a second substrate structure including memory cells and an input and output pad electrically connected to the first to fourth circuit elements; and
a controller electrically connected to the semiconductor storage device through the input and output pad and controlling the semiconductor storage device,
wherein the first circuit elements include NMOS transistors for low-voltage driving, the second circuit elements include PMOS transistors for low-voltage driving, the third circuit elements include NMOS transistors for high-voltage driving, and the fourth circuit elements include PMOS transistors for high-voltage driving, and
wherein each of the third circuit elements includes:
a gate structure on an upper surface of the substrate, the gate structure including a gate dielectric layer having a thickness greater than a thickness of gate dielectric layers of the first and second circuit elements, and a gate conductive layer on the gate dielectric layer;
a drain region disposed in the substrate and extending from the upper surface of the substrate on a first side of the gate structure in a first direction parallel to the upper surface of the substrate;
a source region disposed in the substrate, extending from the upper surface of the substrate on a second side of the gate structure opposite to the first side of the gate structure in the first direction;
a channel region disposed in the substrate and extending from the upper surface of the substrate, below the gate structure, and between the drain region and the source region; and
a separation trench structure extending from a lower surface of the substrate in a second direction perpendicular to the first direction, the separation trench structure disposed in a boundary region between the channel region and the drain region, the separation trench structure having an upper end spaced apart from the upper surface of the substrate.
